(19) United States
(12) Patent Application Publication
(10) Pub. No.: US 2026/0324195 A1
(43) Pub. Date: Oct. 15, 2026

(54) DISPLAY DEVICE, METHOD FOR MANUFACTURING THE SAME, AND ELECTRONIC DEVICE INCLUDING THE SAME

(71) Applicant: Samsung Display Co., Ltd., Yongin-si (KR)

(72) Inventors: Aeran Song, Yongin-si (KR); HYUNGJUN KIM, Yongin-si (KR); SOYOUNG KOO, Yongin-si (KR); Minjae Kim, Yongin-si (KR); GEUNCHUL PARK, Yongin-si (KR); JOON SEOK PARK, Yongin-si (KR)

(21) Appl. No.: 19/427,043

(22) Filed: Dec. 19, 2025

(30) Foreign Application Priority Data
Apr. 11, 2025 (KR) 10-2025-0047474

(51) Int. Cl. H10K 59/121; H10K 59/12; H10K 59/124

(52) U.S. Cl. CPC H10K 59/1213; H10K 59/1201; H10K 59/124

(57) ABSTRACT

A display device includes: a substate including a display area and a peripheral area surrounding at least a portion of the display area; a plurality of sub-pixels in the display area on the substrate; a first transistor of a gate driver in the peripheral area on the substrate; a second transistor of the gate driver in the peripheral area on the first transistor; and an inorganic insulating layer covering the second transistor and defining a plurality of through holes adjacent to the second transistor and spaced apart from each other.

### CROSS-REFERENCE TO RELATED APPLICATION

The present application claims priority to and the benefit of Korean Patent Application No. 10-2025-0047474, filed on Apr. 11, 2025, in the Korean Intellectual Property Office, the entire disclosure of which is incorporated herein by reference.

### BACKGROUND

### 1. Field

Aspects of some embodiments of the present disclosure relate to a display device, a method for manufacturing the same, and an electronic device including the same.

### 2. Description of the Related Art

As information technology develops, the importance of display devices, which provide communication medium between users and information, is being highlighted. Accordingly, the use of display devices such as liquid crystal display devices, organic light emitting display devices, plasma display devices, and the like is increasing.

A display device may display an image (e.g., a set or predetermined image) by including a driving transistor and a light-emitting element which receives driving current from the driving transistor and emits light. To provide driving current to the light-emitting element, drivers, lines, and the like may be arranged in a peripheral area of the display device.

The peripheral area where no light-emitting element is located does not display images. The peripheral area where the image is not displayed may be referred to as a dead space. Recently, there has been a growing demand to relatively reduce dead space in the display device.

The above information disclosed in this Background section is only for enhancement of understanding of the background and therefore the information discussed in this Background section does not necessarily constitute prior art.

### SUMMARY

Aspects of some embodiments of the present disclosure relate to a display device, a method for manufacturing the same, and an electronic device including the same. For example, aspects of some embodiments of the present disclosure relate to the display device which provides visual information, the method for manufacturing the same, and the electronic device including the same.

Aspects of some embodiments include a display device for relatively reducing dead spaced and preventing or reducing degradation of transistor characteristics.

Aspects of some embodiments include a method for manufacturing the display device.

Aspects of some embodiments include an electronic device including the display device.

A display device according to some embodiments of the present disclosure include a substate including a display area and a peripheral area surrounding at least a portion of the display area, a plurality of sub-pixels in the display area on the substrate, a first transistor of a gate driver in the peripheral area on the substrate, a second transistor of the gate driver in the peripheral area on the first transistor, and an inorganic insulating layer covering the second transistor and defining a plurality of through holes adjacent to the second transistor and spaced apart from each other.

According to some embodiments, an insulating material may be filled inside the plurality of through holes.

According to some embodiments, the display device may further include a via insulating layer on the inorganic insulating layer, filling interiors of the plurality of through holes, and including an organic material.

According to some embodiments, the first transistor and the second transistor may include a metal oxide semiconductor.

According to some embodiments, the second transistor may include an upper active pattern including a metal oxide semiconductor and an upper gate electrode overlapping a channel region of the upper active pattern in a plan view.

According to some embodiments, the display device may further include a middle connection pattern connected to a conductive region of the upper active pattern through a contact hole penetrating the inorganic insulating layer in the peripheral area.

According to some embodiments, the display device may further include a first interlayer insulating layer covering the first transistor, a second interlayer insulating layer on the first interlayer insulating, and a buffer layer between the second interlayer insulating layer and the second transistor, each of the plurality of through holes may expose at least a portion of the buffer layer.

According to some embodiments, a pitch between two adjacent through holes among the plurality of through holes may be in a range of 10 micrometers (μm) or more and 15 micrometers (μm) or less.

According to some embodiments, the plurality of through holes may include a plurality of first through holes adjacent to the second transistor and spaced apart from each other in the peripheral area and a plurality of second through holes spaced apart from each other in the display area.

According to some embodiments, each of the plurality of sub-pixels may include a plurality of transistors including a metal oxide semiconductor.

According to some embodiments, each of the plurality of transistors may include a first lower active pattern and the first transistor includes a second lower active pattern in a same layer as the first lower active pattern.

A method for manufacturing a display device according to some embodiments of the present disclosure includes forming a plurality of sub-pixels in a display area on a substrate including the display area and a peripheral area surrounding at least a portion of the display area, forming a first transistor of a gate driver in the peripheral area on the substrate, forming a second transistor of the gate driver in the peripheral area on the first transistor, forming an inorganic insulating layer covering the second transistor, and forming a plurality of through holes adjacent to the second transistor and spaced apart from each other by penetrating the inorganic insulating layer.

According to some embodiments, the method may further include forming a via insulating layer filling interiors of the plurality of through holes and including an organic material on the inorganic insulating layer.

According to some embodiments, the first transistor and the second transistor may include a metal oxide semiconductor.

According to some embodiments, the forming the second transistor may include forming an upper active pattern including a metal oxide semiconductor and forming an upper gate electrode overlapping a channel region of the upper active pattern in a plan view.

According to some embodiments, the method may further include forming a contact hole penetrating the inorganic insulating layer and exposing a conductive region of the upper active pattern and forming a middle connection pattern connected to the conductive region of the upper active pattern through the contact hole.

According to some embodiments, the plurality of through holes may be formed through a same process as the contact hole.

According to some embodiments, the plurality of through holes may include a plurality of first through holes adjacent to the second transistor and spaced apart from each other in the peripheral area and a plurality of second through holes spaced apart from each other in the display area.

An electronic device according to some embodiments of the present disclosure includes a processor which provides an image data signal and an input control signal and a display device which outputs image information based on the image data signal and the input control signal, the display device includes: a substate including a display area and a peripheral area surrounding at least a portion of the display area, a plurality of sub-pixels in the display area on the substrate, a first transistor of a gate driver in the peripheral area on the substrate and including a metal oxide semiconductor, a second transistor of the gate driver in the peripheral area on the first transistor and including a metal oxide semiconductor, and an inorganic insulating layer covering the second transistor and defining a plurality of through holes adjacent to the second transistor and spaced apart from each other.

According to some embodiments, the display device may further include a via insulating layer on the inorganic insulating layer, filling interiors of the plurality of through holes, and including an organic material.

In a display device according to some embodiments of the present disclosure, in a peripheral area, in a structure in which a first transistor of a first circuit layer including a metal oxide semiconductor and a second transistor of a second circuit layer including a metal oxide semiconductor are stacked along a thickness direction, a plurality of through holes spaced apart from each other may be defined in an inorganic insulating layer (i.e., a third interlayer insulating layer) included in the second circuit layer. Accordingly, hydrogen, which is generated from insulating layers included in the first circuit layer and may serve as a carrier in case that absorbed into a lower active pattern of the first transistor, may diffuse (or be discharged) to the outside (i.e., the second circuit layer) through the plurality of through holes. In this case, the characteristics of a lower element included in the first circuit layer may not deteriorate, and the variation of the lower element may be relatively reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to some embodiments of the present disclosure.

FIG. 2 is a circuit diagram illustrating a circuit structure of one sub-pixel of FIG. 1.

FIG. 3 is a circuit diagram schematically illustrating a stage included in a first gate driver or a second gate driver of FIG. 1.

FIG. 4 is a cross-sectional view taken along line I-I′ of FIG. 1.

FIG. 5 is a plan view illustrating an enlarged portion of a peripheral area of FIGS. 1 and 4.

FIG. 6 is a plan view illustrating an enlarged portion of a display area of FIGS. 1 and 4.

FIGS. 7 to 20 are cross-sectional views for explaining a method for manufacturing the display device of FIG. 4.

FIG. 21 is a graph for explaining a change in a threshold voltage (Vth) of an upper element according to a pitch between through holes in comparative examples and embodiments.

FIG. 22 is a graph for explaining a change in a threshold voltage (Vth) of a lower element according to the pitch between through holes in comparative examples and embodiments.

FIG. 23 is a graph for explaining a change in a drain-source current (Ids) according to a gate-source voltage (Vgs) of a lower element in a comparative example.

FIG. 24 is a graph for explaining a change in a drain-source current (Ids) according to a gate-source voltage (Vgs) of a lower element according to some embodiments.

FIG. 25 is a block diagram illustrating an electronic device according to some embodiments of the present disclosure.

FIG. 26 is a schematic diagram illustrating an electronic device according to various embodiments.

### DETAILED DESCRIPTION OF THE EMBODIMENTS

Hereinafter, aspects of some embodiments of the present disclosure will be explained in more detail with reference to the accompanying drawings. The same reference numerals are used for the same components in the drawings, and some redundant descriptions of the same components may be omitted.

In the present specification, a plane may be defined by a first direction D1 and a second direction D2 intersecting the first direction D1. For example, the first direction D1 may be perpendicular to the second direction D2. In addition, a third direction D3 may be a normal direction of the plane. That is, the third direction D3 may be perpendicular to the plane.

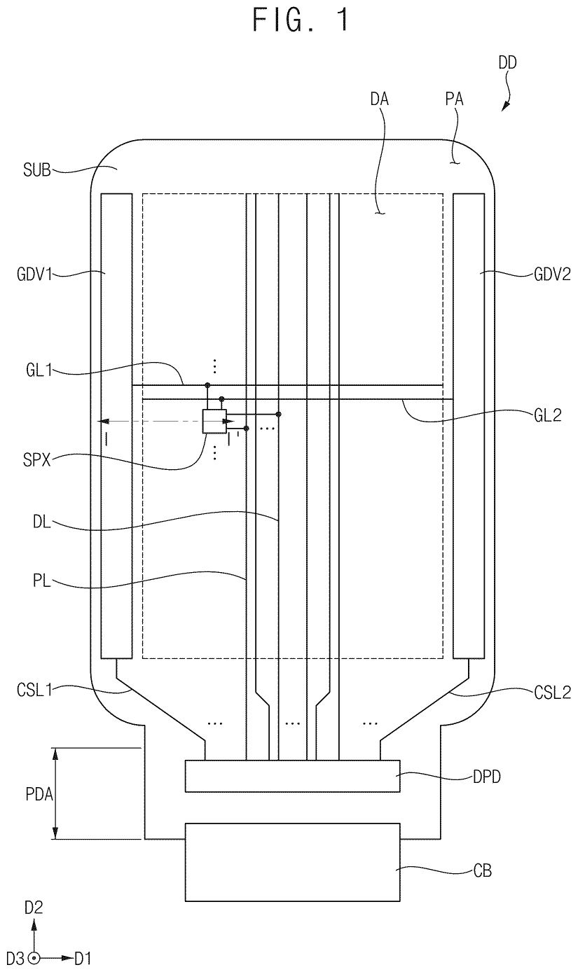

FIG. 1 is a plan view illustrating a display device according to some embodiments of the present disclosure.

Referring to FIG. 1, a display device DD according to some embodiments of the present disclosure may include a plurality of sub-pixels SPX, a first gate driver GDV1, a second gate driver GDV2, a first gate signal line GL1, a second gate signal line GL2, a data line DL, a power line PL, a first control signal line CSL1, a second control signal line CSL2, a display panel driver DPD, and a circuit board CB located on a substrate SUB. Although a single sub-pixel SPX, a single first gate signal line GL1, a single second gate line GL2, a single data line DL, and a single power line PL are shown in FIG. 1, as a person having ordinary skill in the art would appreciate, the display device DD may include any suitable number of the above components according to the design and size of the display device DD.

The substrate SUB may include a display area DA and a peripheral area PA. The display area DA may be an area capable of displaying an image by generating light or controlling a transmittance of light provided from an external light source. The peripheral area PA may be an area which does not display an image. The peripheral area PA may surround at least a portion of the display area DA. For example, the peripheral area PA may entirely surround the display area DA.

The peripheral area PA may include a pad area PDA. The pad area PDA may be located at an end of the peripheral area PA adjacent to a lower side of the display area DA. The pad area PDA may have a shape extending along one side of the display device DD. For example, the pad area PDA may have a shape extending along the first direction D1.

The plurality of sub-pixels SPX may be arranged in the display area DA. Each of the plurality of sub-pixels SPX may include a driving element (e.g., a thin film transistor) which generates a driving current, and a light-emitting element (e.g., an organic light-emitting diode or an inorganic light-emitting diode) electrically connected to the driving element and generating light based on the driving current. Accordingly, each of the plurality of sub-pixels SPX may generate light according to the driving current. The plurality of sub-pixels SPX may be entirely arranged in the display area DA in a matrix form along the first direction D1 and the second direction D2.

Drivers for driving the plurality of sub-pixels SPX may be located in the peripheral area PA. For example, the first gate driver GDV1, the second gate driver GDV2, and the display panel driver DPD may located in the peripheral area PA.

The data line DL, the first gate signal line GL1, the second gate signal line GL2, and the power line PL connected to the plurality of sub-pixels SPX may be located in the display area DA. In addition, the first control signal line CSL1 connected to the first gate driver GDV1 and the second control signal line CSL2 connected to the second gate driver GDV2 may be located in the peripheral area PA.

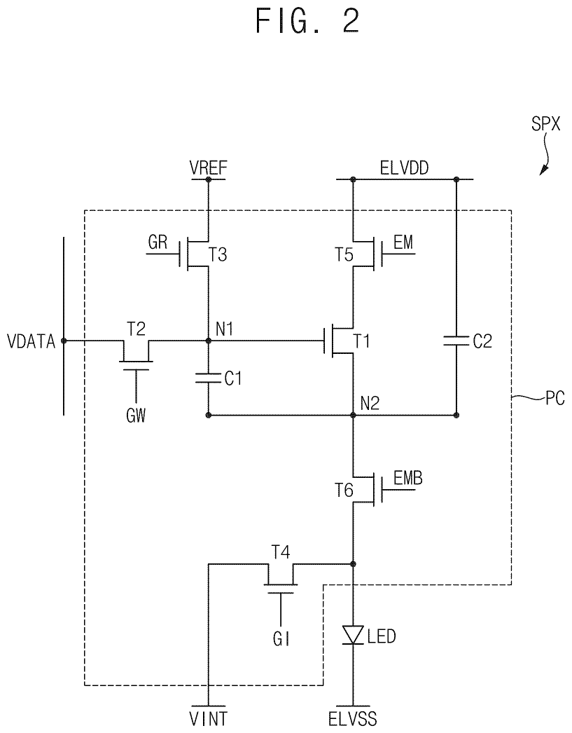

The first gate signal line GL1 may be electrically connected to the first gate driver GDV1 and may extend along the first direction D1. The first gate signal line GL1 may receive a first gate signal from the first gate driver GDV1 and provide the first gate signal to the plurality of sub-pixels SPX. For example, the first gate signal may include at least one of the gate signals GW, GR, or GI of FIG. 2.

The second gate signal line GL2 may be electrically connected to the second gate driver GDV2 and may extend along the first direction D1. The second gate signal line GL2 may receive a second gate signal from the second gate driver GDV2 and provide the second gate signal to the plurality of sub-pixels SPX. For example, the second gate signal may include at least one of the gate signals GW, GR, or GI of FIG. 2.

The data line DL may be electrically connected to the display panel driver DPD and may extend along the second direction D2. The data line DL may receive a data voltage (e.g., VDATA of FIG. 2) from the display panel driver DPD and provide the data voltage through the data line DL. The data line DL may provide the data voltage to the plurality of sub-pixels SPX.

The power line PL may be electrically connected to the display panel driver DPD and may extend along the second direction D2. The power line PL may receive a power voltage (e.g., ELVDD of FIG. 2) from the display panel driver DPD and provide the power voltage to the plurality of sub-pixels SPX. For example, the power voltage may be a high power voltage for driving the plurality of sub-pixels SPX.

The first control signal line CSL1 may be electrically connected to the display panel driver DPD. The first control signal line CSL1 may receive a first control signal from the display panel driver DPD and provide the first control signal to the first gate driver GDV1.

The second control signal line CSL2 may be electrically connected to the display panel driver DPD. The second control signal line CSL2 may receive a second control signal from the display panel driver DPD and provide the second control signal to the second gate driver GDV2.

The display panel driver DPD may be located in the pad area PDA. The display panel driver DPD may be formed as an integrated circuit IC. For example, in case that the substrate SUB of the display device DD includes glass, the display panel driver DPD may be a chip on glass (COG) structure directly located on the substrate SUB. Alternatively, in case that the substrate SUB includes plastic, the display panel driver DPD may be a chip on plastic (COP) structure directly located on the substrate SUB. The embodiments of the present disclosure are not necessarily limited thereto.

The display panel driver DPD may transmit various signals and/or voltages. For example, the display panel driver DPD may transmit the first control signal, the second control signal, the power voltage, the data voltage, and the like. That is, the display panel driver DPD may include a data driver for transmitting the data voltage, a timing controller for transmitting the first and second control signals, and a power supplier for transmitting the power voltage. Alternatively, the timing controller and the power supplier may be located outside of the display panel driver DPD.

The first gate driver GDV1 may be located in the peripheral area PA. For example, the first gate driver GDV1 may be located in the peripheral area PA adjacent to a left edge of the display area DA. The first gate driver GDV1 may receive the first control signal from the display panel driver DPD and may generate the first gate signal based on the first control signal.

The second gate driver GDV2 may be located in the peripheral area PA. For example, the second gate driver GDV2 may be located in the peripheral area PA adjacent to a right edge of the display area DA. The second gate driver GDV2 may receive the second control signal from the display panel driver DPD and may generate the second gate signal based on the second control signal.

The first gate driver GDV1 and the second gate driver GDV2 may respectively include a plurality of transistors. According to some embodiments, each of the plurality of transistors included in the first gate driver GDV1 and the second gate driver GDV2 may include a metal oxide semiconductor.

The display device DD may further include an emission driver which is located in the peripheral area PA and generates an emission control signal. The emission driver may provide the emission control signal to the plurality of sub-pixels SPX. For example, the emission control signal may include at least one of emission control signals EB or EMB of FIG. 2.

The circuit board CB may be located in the pad area PDA. Specifically, the circuit board CB may partially overlap the pad area PDA. That is, a first portion of the circuit board CB may overlap the pad area PDA, and a second portion of the circuit board CB excluding the first portion may not overlap the pad area PDA. The circuit board CB may be bonded to the pad area PDA through an adhesive member (e.g., an anisotropic conductive film). The circuit board CB may provide voltages, control signals, and the like to the display panel driver DPD.

For example, the circuit board CB may include a printed circuit board PCB, a flexible printed circuit board FPCB, or a flexible flat cable FFC. The embodiments of the present disclosure are not necessarily limited thereto.

FIG. 2 is a circuit diagram illustrating a circuit structure of one sub-pixel of FIG. 1. Although FIG. 2 illustrates various components in a sub-pixel according to some embodiments, embodiments according to the present disclosure are not limited thereto, and according to various embodiments, the sub-pixel may include additional components, or fewer components, without departing from the spirit and scope of embodiments according to the present disclosure.

Referring to FIG. 2, one sub-pixel SPX may include a pixel driving circuit part PC and a light-emitting element LED electrically connected to the pixel driving circuit part PC. The pixel driving circuit part PC may generate a driving current, and the light-emitting element LED may generate light based on the driving current.

According to some embodiments, the pixel circuit part PC may include a first transistor T1, a second transistor T2, a third transistor T3, a fourth transistor T4, a fifth transistor T5, a sixth transistor T6, a first capacitor C1, and a second capacitor C2.

According to some embodiments, the first transistor T1, the second transistor T2, the third transistor T3, the fourth transistor T4, the fifth transistor T5, and the sixth transistor T6 may all be NMOS transistors. However, the embodiments of the present disclosure are not necessarily limited thereto, and some of the first transistor T1, the second transistor T2, the third transistor T3, the fourth transistor T4, the fifth transistor T5, and the sixth transistor T6 may be NMOS transistors, and the others may be PMOS transistors.

In case that the pixel driving circuit part PC includes NMOS transistor and PMOS transistor, an active pattern of the NMOS transistor may include a metal oxide semiconductor, and an active pattern of the PMOS transistor may include a silicon semiconductor. However, the embodiments of the present disclosure are not necessarily limited thereto, and the active pattern of the NMOS transistor may include a silicon semiconductor, and the active pattern of the PMOS transistor may include a metal oxide semiconductor.

The first transistor T1 may include a gate electrode, a first electrode, and a second electrode. The gate electrode of the first transistor T1 may be connected to a first node N1. The first electrode of the first transistor T1 may be connected to the fifth transistor T5. The second electrode of the first transistor T1 may be connected to a second node N2. The first transistor T1 may provide the driving current to the light-emitting element LED.

The second transistor T2 may include a gate electrode, a first electrode, and a second electrode. The gate electrode of the second transistor T2 may receive the first gate signal GW. The first electrode of the second transistor T2 may receive the data voltage VDATA. The second electrode of the second transistor T2 may be connected to the first node N1.

The second transistor T2 may be turned on or turned off in response to the first gate signal GW. For example, in case that the first gate signal GW has an active level, the second transistor T2 may be turned on. In this case, the second transistor T2 may provide the data voltage VDATA to the first node N1. Conversely, in case that the first gate signal GW has an inactive level, the second transistor T2 may be turned off. In this case, the second transistor T2 may block supply of the data voltage VDATA.

The third transistor T3 may include a gate electrode, a first electrode, and a second electrode. The gate electrode of the third transistor T3 may receive the second gate signal GR. The first electrode of the third transistor T3 may receive a reference voltage VREF. The second electrode of the third transistor T3 may be connected to the first node N1. For example, the reference voltage VREF may have a voltage level different from or the same as a common voltage ELVSS.

The third transistor T3 may be turned on or turned off in response to the second gate signal GR. For example, in case that the second gate signal GR has an active level, the third transistor T3 may be turned on. In this case, the third transistor T3 may provide the reference voltage VREF to the first node N1. Conversely, in case that the second gate signal GR has an inactive level, the third transistor T3 may be turned off. In this case, the third transistor T3 may block supply of the reference voltage VREF.

The fourth transistor T4 may include a gate electrode, a first electrode, and a second electrode. The gate electrode of the fourth transistor T4 may receive the third gate signal GI. The first electrode of the fourth transistor T4 may receive an initialization voltage VINT. The second electrode of the fourth transistor T4 may be connected between the sixth transistor T6 and the light-emitting element LED. For example, the initialization voltage VINT may have a voltage level different from or the same as the common voltage ELVSS.

The fourth transistor T4 may be turned on or turned off in response to the third gate signal GI. For example, in case that the third gate signal GI has an active level, the fourth transistor T4 may be turned on. In this case, the fourth transistor T4 may provide the initialization voltage VINT to a node between the sixth transistor T6 and the light-emitting element LED. Conversely, in case that the third gate signal GI has an inactive level, the fourth transistor T4 may be turned off. In this case, the fourth transistor T4 may block supply of the initialization voltage VINT.

The fifth transistor T5 may include a gate electrode, a first electrode, and a second electrode. The gate electrode of the fifth transistor T5 may receive the first emission control signal EM. The first electrode of the fifth transistor T5 may receive a driving voltage ELVDD. The second electrode of the fifth transistor T5 may be connected to the first transistor T1.

The fifth transistor T5 may be turned on or turned off in response to the first light-emission control signal EM. For example, in case that the first emission control signal EM has an active level, the fifth transistor T5 may be turned on. In this case, the fifth transistor T5 may provide the driving current generated in the first transistor T1 to an anode electrode of the light-emitting element LED. Conversely, in case that the first emission control signal EM has an inactive level, the fifth transistor T5 may block supply of the driving current generated in the first transistor T1.

The sixth transistor T6 may include a gate electrode, a first electrode, and a second electrode. The gate electrode of the sixth transistor T6 may receive a second emission control signal EMB. The first electrode of the sixth transistor T6 may be connected to the second node N2. The second electrode of the sixth transistor T6 may be connected to the anode electrode of the light-emitting element LED.

The sixth transistor T6 may be turned on or turned off in response to the second light-emission control signal EMB. For example, in case that the second emission control signal EMB has an active level, the sixth transistor T6 may be turned on. In this case, the sixth transistor T6 may provide the driving current generated in the first transistor T1 to the anode electrode of the light-emitting element LED. Conversely, in case that the second light-emission control signal EMB has an inactive level, the sixth transistor T6 may be turned off. In this case, the sixth transistor T6 may block supply of the driving current generated in the first transistor T1.

According to some embodiments, a first electrode of each of the first, second, third, fourth, fifth, and sixth transistors T1, T2, T3, T4, T5, and T6 may be a drain electrode, and a second electrode of each of the first to sixth transistors T1, T2, T3, T4, T5, and T6 may be a source electrode. However, the embodiments of the present disclosure are not necessarily limited thereto.

The first capacitor C1 may include a first electrode and a second electrode. The first electrode of the first capacitor C1 may be connected to the first node N1. The second electrode of the first capacitor C1 may be connected to the second node N2. The first capacitor C1 may store a voltage corresponding to a difference between a voltage of the first node N1 and a voltage of the second node N2. Therefore, the first capacitor C1 may be referred to as a storage capacitor.

The second capacitor C2 may include a first electrode and a second electrode. The first electrode of the second capacitor C2 may receive the driving voltage ELVDD. The second electrode of the second capacitor C2 may be connected to the second node N2. The second capacitor C2 may be a capacitor for maintaining a voltage of the second node N2. Therefore, the second capacitor C2 may be referred to as a holding capacitor.

The light-emitting element LED may include an anode electrode and a cathode electrode. The anode electrode of the light-emitting element LED may be connected to the second electrode of the fourth transistor T4 and the second electrode of the sixth transistor T6. The cathode electrode of the light-emitting element LED may receive the common voltage ELVSS. For example, the common voltage ELVSS may have a voltage level lower than the driving voltage ELVDD.

Although one pixel circuit part PC is illustrated in FIG. 2 as including six transistors and two capacitors, the embodiments of the present disclosure are not necessarily limited thereto.

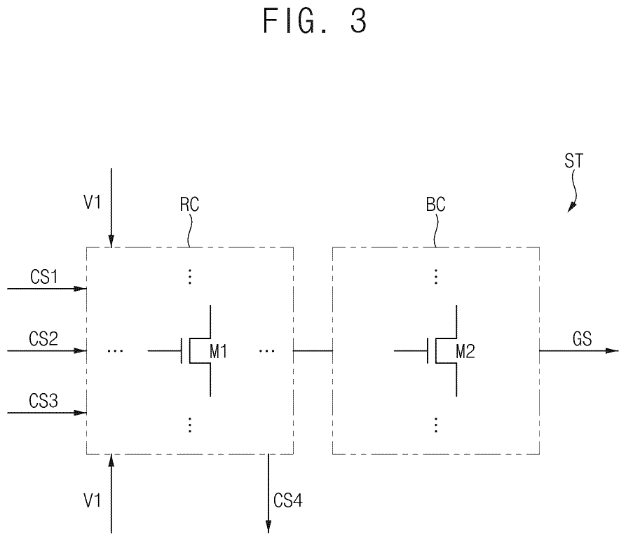

FIG. 3 is a circuit diagram schematically illustrating a stage included in a first gate driver or a second gate driver of FIG. 1.

Referring to FIG. 3, the first gate driver GDV1 or the second gate driver GDV1 may include a stage ST. For example, the stage ST included in the first gate driver GDV1 or the second gate driver GDV1 may be a plurality.

The stage ST may include a logic circuit part RC and a buffer circuit part BC electrically connected to the logic circuit part RC. The logic circuit part RC may control the buffer circuit part BC, and the buffer circuit part BC may output a driving signal (i.e., the gate signal GS).

The logic circuit part RC includes a first transistor M1, and the buffer circuit part BC may include a second transistor M2. According to some embodiments, the first transistor M1 and the second transistor M2 may include a metal oxide semiconductor. For convenience of explanation, in FIG. 3, each of the logic circuit part RC and the buffer circuit part BC is illustrated as including one transistor, but the logic circuit part RC may include a plurality of transistors, and the buffer circuit part BC may include at least one transistor.

The logic circuit part RC may receive various control signals CS1, CS2, and CS3 and voltages V1 and V2, and may output a carry signal CS4. The carry signal CS4 may be provided to a subsequent stage. The buffer circuit part BC may output the gate signal GS.

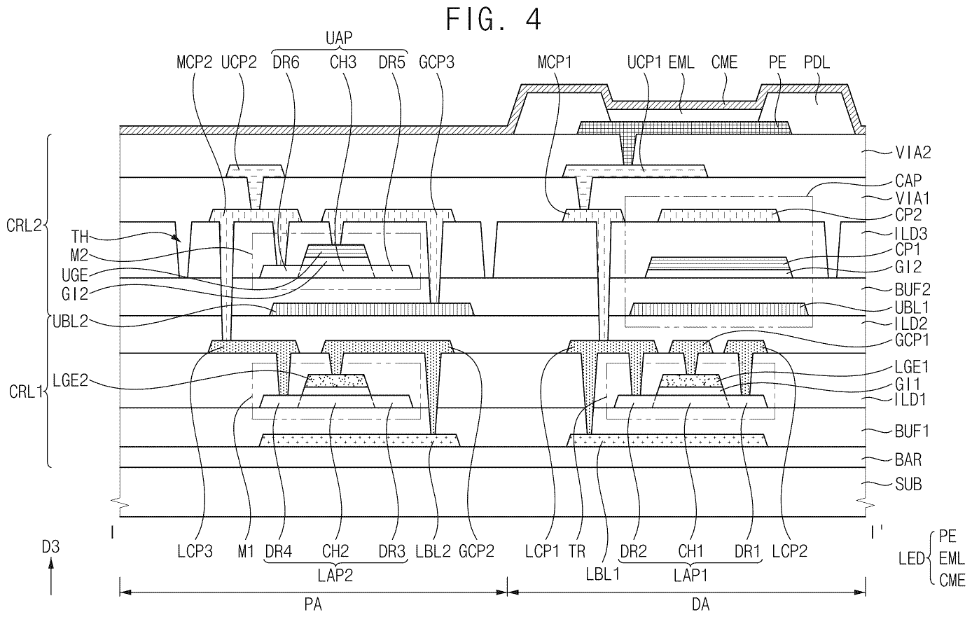

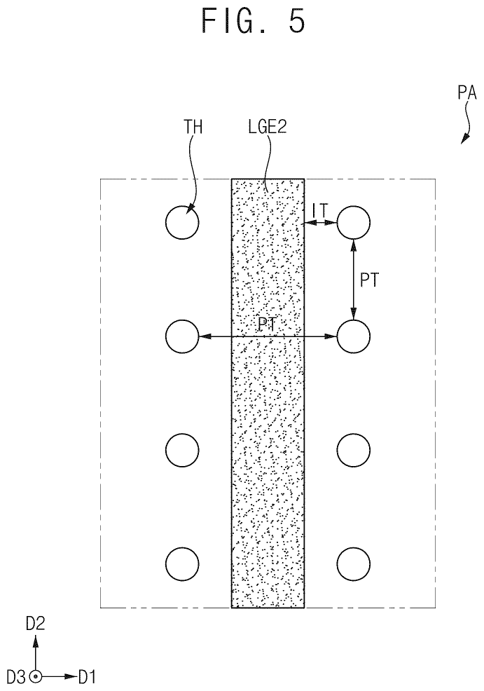

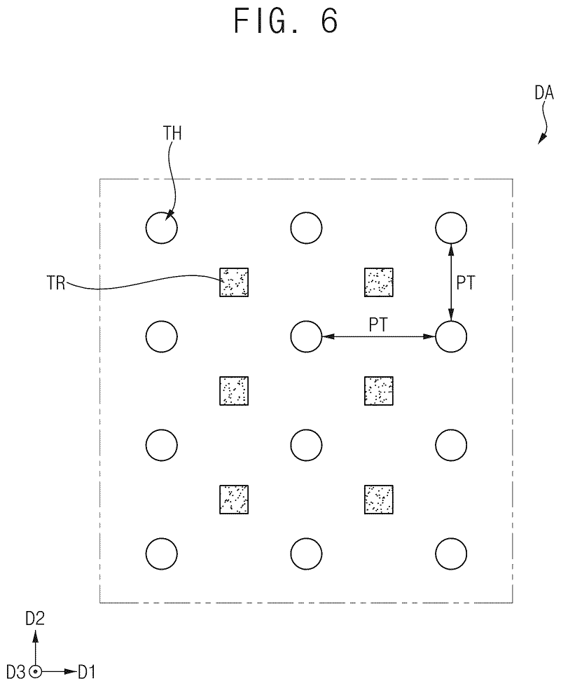

FIG. 4 is a cross-sectional view taken along the line I-I′ of FIG. 1. FIG. 5 is a plan view illustrating an enlarged portion of a peripheral area of FIGS. 1 and 4. FIG. 6 is a plan view illustrating an enlarged portion of a display area of FIGS. 1 and 4.

Referring to FIGS. 4 to 6, the display device DD according to some embodiments of the present disclosure may include a substrate SUB, a first circuit layer CRL1 located on the substrate SUB, a second circuit layer CRL2 located on the first circuit layer CRL1, and a light-emitting element layer located on the second circuit layer CRL2.

The first circuit layer CRL1 may include a barrier layer BAR, first and second lower metal layers LBL1 and LBL2, a first buffer layer BUF1, a transistor TR, a first transistor M1, a first gate insulating layer GI1, a first interlayer insulating layer ILD1, first, second, and third lower connection patterns LCP1, LCP2, and LCP3, first and second gate connection patterns GCP1 and GCP2, and a second interlayer insulating layer ILD2.

The second circuit layer CRL2 may include third and fourth lower metal layers UBL1 and UBL2, a second buffer layer BUF2, a second transistor M2, a second gate insulating layer GI2, a first conductive pattern CP1, a third interlayer insulating layer ILD3, a second conductive pattern CP2, first and second middle connection patterns MCP1 and MCP2, a third gate connection pattern GCP3, a first via insulating layer VIA1, first and second upper connection patterns UCP1 and UCP2, and a second via insulating layer VIA2.

The light-emitting element layer may include a pixel defining layer PDL and a light-emitting element LED. The light-emitting element LED may include a pixel electrode PE, a light-emitting layer EML, and a common electrode CME.

The substrate SUB may include a glass substrate, a metal substrate, a plastic substrate, and the like. However, the embodiments of the present disclosure are not necessarily limited thereto. For example, the substrate SUB may include an inorganic layer, an organic layer, or a composite material layer. In addition, the substrate SUB may include a flexible substrate having flexibility.

The barrier layer BAR may be located on the substrate SUB. The barrier layer BAR may be located in the display area DA and the peripheral area PA. The barrier layer BAR may prevent or reduce instances of contaminants or foreign substances entering from the outside. The barrier layer BAR may include an inorganic insulating material such as silicon oxide (SiOₓ), silicon nitride (SiNₓ), silicon oxynitride (SiOₓN_{y}), and the like. These may be used alone or in combination with each other. The barrier layer BAR may have a single-layer structure or a multi-layer structure in which a plurality of layers is stacked.

The first and second lower metal layers LBL1 and LBL2 may be located on the barrier layer BAR. The first lower metal layer LBL1 may be located in the display area DA, and the second lower metal layer LBL2 may be located in the peripheral area PA. The first lower metal layer LBL1 may block light incident on the transistor TR from the outside, and the second lower metal layer LBL2 may block light incident on the first transistor M1 from the outside. For example, the first and second lower metal layers LBL1 and LBL2 may include molybdenum (Mo), an alloy containing molybdenum, titanium (Ti), an alloy containing titanium, and the like. These may be used alone or in combination with each other. However, the embodiments of the present disclosure are not necessarily limited thereto. Each of the first and second lower metal layers LBL1 and LBL2 may have a single-layer structure or a multi-layer structure in which a plurality of layers is stacked.

The first and second lower metal layers LBL1 and LBL2 may be located in the same layer. That is, the first and second lower metal layers LBL1 and LBL2 may include the same material and may be formed through the same process.

The first buffer layer BUF1 may be located on the barrier layer BAR. The first buffer layer BUF1 may cover the first and second lower metal layers LBL1 and LBL2. The first buffer layer BUF1 may prevent or reduce instances of contaminants such as metal atoms or impurities the substrate SUB from diffusing into the transistor TR and the first transistor M1. In addition, in case that a surface of the substrate SUB is not uniform, the first buffer layer BUF1 may relatively improve flatness of the surface of the substrate SUB. For example, the first buffer layer BUF1 may include an inorganic insulating material such as silicon oxide (SiOₓ), silicon nitride (SiNₓ), silicon oxynitride (SiOₓN_{y}), and the like. These may be used alone or in combination. The first buffer layer BUF1 may have a single-layer structure or a multilayer structure in which a plurality of layers is stacked.

The first and second lower active patterns LAP1 and LAP2 may be located on the first buffer layer BUF1. The first lower active pattern LAP1 may be located in the display area DA, and the second lower active pattern LAP2 may be located in the peripheral area PA. According to some embodiments, the first and second lower active patterns LAP1 and LAP2 may include a metal oxide semiconductor. For example, the metal oxide semiconductor may include zinc oxide (e.g., ZnO or ZnO₂), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), and the like. These may be used alone or in combination with each other. According to some embodiments, the first and second lower active patterns LAP1 and LAP2 may include indium gallium zinc oxide (IGZO).

The first and second lower active patterns LAP1 and LAP2 may be located in the same layer. That is, the first and second lower active patterns LAP1 and LAP2 may include the same material and may be formed through the same process.

The first lower active pattern LAP1 may include a first conductive region DR1, a second conductive region DR2, and a first channel region CH1 between the first conductive region DR1 and the second conductive region DR2. The first and second conductive regions DR1 and DR2 may have higher conductivity than the first channel region CH1.

The second lower active pattern LAP2 may include a third conductive region DR3, a fourth conductive region DR4, and a second channel region CH2 between the third conductive region DR3 and the fourth conductive region DR4. The third and fourth conductive regions DR3 and DR4 may have higher conductivity than the second channel region CH2.

The first gate insulating layer GI1 may be located on the first and second lower active patterns LAP1 and LAP2. The first gate insulating layer GI1 may be respectively located in the display area DA and the peripheral area PA and may be patterned to overlap the first channel region CH1 and the second channel region CH2 in the plan view, respectively. For example, the first gate insulating layer GI1 may include an inorganic insulating material such as silicon oxide (SiOₓ), silicon nitride (SiNₓ), silicon oxynitride (SiOₓN_{y}), and the like. These may be used alone or in combination with each other. The first gate insulating layer GI1 may have a single-layer structure or a multi-layer structure in which a plurality of layers is stacked.

The first and second lower gate electrodes LGE1 and LGE2 may be located on the first gate insulating layer GI1. The first lower gate electrode LGE1 may be located on the first gate insulating layer GI1 in the display area DA and may overlap the first channel region CH1 in the plan view. The second lower gate electrode LGE2 may be located on the first gate insulating layer GI1 in the peripheral area PA and may overlap the second channel region CH2 in the plan view.

The first and second lower gate electrodes LGE1 and LGE2 may include a metal, an alloy, a metal nitride, a conductive metal oxide, a transparent conductive material, and the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide may include indium tin oxide, indium zinc oxide, and the like. Examples of the metal nitride may include aluminum nitride (AlNₓ), tungsten nitride (WNₓ), chromium nitride (CrNₓ), and the like. These may be used alone or in combination with each other. The first and second lower gate electrodes LGE1 and LGE2 may respectively have a multilayer structure or a multi-layer structure in which a plurality of layers are stacked.

The first and second lower gate electrodes LGE1 and LGE2 may be located in the same layer. That is, the first and second lower gate electrodes LGE1 and LGE2 may include the same material and may be formed through the same process.

Accordingly, the transistor TR including the first lower active pattern LAP1 and the first lower gate electrode LGE1 may be formed in the display area DA, and the first transistor M1 including the second lower active pattern LAP2 and the second lower gate electrode LGE2 may be formed in the peripheral area PA. For example, the transistor TR of FIG. 4 may correspond to the first transistor T1 of FIG. 2, and the first transistor M1 of FIG. 4 may correspond to the first transistor M1 of FIG. 3.

The first interlayer insulating layer ILD1 may be located on the first buffer layer BUF1. The first interlayer insulating layer ILD1 may be located in the display area DA and the peripheral area PA. The first interlayer insulating layer ILD1 may cover the first transistor M1 and the transistor TR. For example, the first interlayer insulating layer ILD1 may include an inorganic insulating material such as silicon oxide (SiOₓ), silicon nitride (SiNₓ), silicon oxynitride (SiOₓN_{y}), and the like. These may be used alone or in combination with each other. The first interlayer insulating layer ILD1 may have a single-layer structure or a multi-layer structure in which a plurality of layers is stacked.

The first, second, and third lower connection patterns LCP1, LCP2, and LCP3 and the first and second gate connection patterns GCP1 and GCP2 may be located on the first interlayer insulating layer ILD1. The first and second lower connection patterns LCP1 and LCP2 and the first gate connection pattern GCP1 may be located in the display area DA, and the third lower connection pattern LCP3 and the second gate connection pattern GCP2 may be located in the peripheral area PA.

The first lower connection pattern LCP1 may be connected to the second conductive region DR2 of the first lower active pattern LAP1 through a contact hole penetrating the first interlayer insulating layer ILD1, and may be connected to the first lower metal layer LBL1 through a contact hole penetrating the first buffer layer BUF1 and the first interlayer insulating layer ILD1. The second lower connection pattern LCP2 may be connected to the first conductive region DR1 of the first lower active pattern LAP1 through a contact hole penetrating the first interlayer insulating layer ILD1. The first gate connection pattern GCP1 may be connected to the first lower gate electrode LGE1 through a contact hole penetrating the first interlayer insulating layer ILD1.

In addition, the third lower connection pattern LCP3 may be connected to the fourth conductive region DR4 of the second lower active pattern LAP2 through a contact hole penetrating the first interlayer insulating layer ILD1. The second gate connection pattern GCP2 may be connected to the second lower gate electrode LGE2 through a contact hole penetrating the first interlayer insulating layer ILD1, and may be connected to the second lower metal layer LBL2 through a contact hole penetrating the first buffer layer BUF1 and the first interlayer insulating layer ILD1.

For example, the first, second, and third lower connection patterns LCP1, LCP2, and LCP3 and the first and second gate connection patterns GCP1 and GCP2 may include a metal, an alloy, a metal nitride, a conductive metal oxide, a transparent conductive material, and the like. These may be used alone or in combination with each other. The first, second, and third lower connection patterns LCP1, LCP2, and LCP3 and the first and second gate connection patterns GCP1 and GCP2 may respectively have a single-layer structure or a multi-layer structure in which a plurality of layers are stacked.

The first, second, and third lower connection patterns LCP1, LCP2, and LCP3 and the first and second gate connection patterns GCP1 and GCP2 may include the same material and may be located in the same layer. That is, the first, second, and third lower connection patterns LCP1, LCP2, and LCP3 and the first and second gate connection patterns GCP1 and GCP2 may be formed through the same process.

The second interlayer insulating layer ILD2 may be located on the first interlayer insulating layer ILD1. The second interlayer insulating layer ILD2 may be located in the display area DA and the peripheral area PA. The second interlayer insulating layer ILD2 may cover the first, second, and third lower connection patterns LCP1, LCP2, and LCP3 and the first and second gate connection patterns GCP1 and GCP2. For example, the second interlayer insulating layer ILD2 may include an inorganic insulating material such as silicon oxide (SiOₓ), silicon nitride (SiNₓ), silicon oxynitride (SiOₓN_{y}). These may be used alone or in combination with each other. The second interlayer insulating layer ILD2 may have a single-layer structure or a multi-layer structure in which a plurality of layers is stacked.

The first circuit layer CRL1 may further include a plurality of switching transistors and a storage capacitor located in the display area DA. The switching transistors may include the second, third, fourth, fifth, and sixth transistors T2, T3, T4, T5, and T6 of FIG. 2. The storage capacitor may correspond to the first capacitor C1 of FIG. 2. The storage capacitor may be configured with a first conductive layer, a second conductive layer, and a third conductive layer sequentially stacked along the third direction D3 on the substrate SUB. In this case, the first conductive layer may be located in the same layer as the first and second lower metal layers LBL1 and LBL2, the second conductive layer may be located in the same layer as the first and second lower gate electrodes LGE1 and LGE2, and the third conductive layer may be located in the same layer as the first, second, and third lower connection patterns LCP1, LCP2, and LCP3 and the first and second gate connection patterns GCP1 and GCP2.

The third and fourth lower metal layers UBL1 and UBL2 may be located on the second interlayer insulating layer ILD2. The third lower metal layer UBL1 may be located in the display area DA, and the fourth lower metal layer UBL2 may be located in the peripheral area PA. The fourth lower metal layer UBL2 may block light incident on the second transistor M2 from the outside. For example, the third and fourth lower metal layers UBL1 and UBL2 may include a metal, an alloy, a metal nitride, a conductive metal oxide, a transparent conductive material, and the like. These may be used alone or in combination with each other. The third and fourth lower metal layers UBL1 and UBL2 may respectively have a single-layer structure or a multi-layer structure in which a plurality of layers is stacked.

The third and fourth lower metal layers UBL1 and UBL2 may be located in the same layer. That is, the third and fourth lower metal layers UBL1 and UBL2 may include the same material and may be formed through the same process.

The second buffer layer BUF2 may be located on the second interlayer insulating layer ILD2. The second buffer layer BUF2 may be located in the display area DA and the peripheral area PA. The second buffer layer BUF2 may prevent or reduce instances of contaminants such as metal atoms or impurities from the substrate SUB from diffusing into the capacitor CAP and the second transistor M2. For example, the second buffer layer BUF2 may include an inorganic insulating material such as silicon oxide (SiOₓ), silicon nitride (SiNₓ), silicon oxynitride (SiOₓN_{y}), and the like. These may be used alone or in combination with each other. The second buffer layer BUF2 may have a single-layer structure or a multi-layer structure in which a plurality of layers is stacked.

The upper active pattern UAP may be located on the second buffer layer BUF2 in the peripheral area PA. According to some embodiments, the upper active pattern UAP may include a metal oxide semiconductor (e.g., indium gallium zinc oxide (IGZO)).

The upper active pattern UAP may include a fifth conductive region DR5, a sixth conductive region DR6, and a third channel region CH3 between the fifth conductive region DR5 and the sixth conductive region DR6. The fifth and sixth conductive regions DR5 and DR6 may have higher conductivity than the third channel region CH3.

The second gate insulating layer GI2 may be located on the second buffer layer BUF2. The second gate insulating layer GI2 may be respectively located in the display area DA and the peripheral area PA. Specifically, the second gate insulating layer GI2 may be arranged in a patterned form in the display area DA and may be arranged in a patterned form to overlap the third channel region CH3 in the plan view in the peripheral area PA. For example, the second gate insulating layer GI2 may include an inorganic insulating material such as silicon oxide (SiOₓ), silicon nitride (SiNₓ), silicon oxynitride (SiOₓN_{y}), and the like. These may be used alone or in combination with each other. The second gate insulating layer GI2 may have a single-layer structure or a multilayer structure in which a plurality of layers is stacked.

The first conductive pattern CP1 and an upper gate electrode UGE may be located on the second gate insulating layer GI2. The first conductive pattern CP1 may overlap the third lower conductive layer UBL1 in the plan view, and the upper gate electrode UGE may overlap the third channel region CH3 in the plan view.

For example, the first conductive pattern CP1 and the upper gate electrode UGE may include a metal, an alloy, a metal nitride, a conductive metal oxide, a transparent conductive material, and the like. These may be used alone or in combination. Each of the first conductive pattern CP1 and the upper gate electrode UGE may have a single-layer structure or a multi-layer structure in which a plurality of layers is stacked.

The first conductive pattern CP1 and the upper gate electrode UGE may be located in the same layer. That is, the first conductive pattern CP1 and the upper gate electrode UGE may include the same material and may be formed through the same process.

Accordingly, the second transistor M2 including the upper active pattern UAP and the upper gate electrode UGE may be formed in the peripheral area PA.

The third interlayer insulating layer ILD3 may be located on the second buffer layer BUF2. The third interlayer insulating layer ILD3 may be located in the display area DA and the peripheral area PA. The third interlayer insulating layer ILD3 may cover the second transistor M2 and the first conductive pattern CP1. For example, the third interlayer insulating layer ILD3 may include an inorganic insulating material such as silicon oxide (SiOₓ), silicon nitride (SiNₓ), silicon oxynitride (SiOₓN_{y}), and the like. These may be used alone or in combination with each other. The third interlayer insulating layer ILD3 may have a single-layer structure or a multi-layer structure in which a plurality of layers is stacked. In the present specification, the third interlayer insulating layer ILD3 may be referred to as an inorganic insulating layer.

According to some embodiments, a plurality of through holes TH adjacent to the second transistor M2 and spaced apart from each other may be defined in the third interlayer insulating layer ILD3. Through the plurality of through-holes TH, hydrogen, which may be generated in insulating layers included in the first circuit layer CRL1 and absorbed into the lower active patterns (e.g., the first lower active pattern LAP1 and/or the second lower active pattern LAP2) and act as a carrier, may diffuse (or be discharged) to the outside (i.e., to the second circuit layer CRL2). That is, the plurality of through holes TH may serve as outgassing holes for discharging hydrogen that affects characteristics of lower elements included in the first circuit layer CRL1 (e.g., the first transistor M1 and/or the transistor TR).

According to some embodiments, the plurality of through holes TH may be located in the peripheral area PA and adjacent to the second transistor M2. However, the embodiments of the present disclosure are not necessarily limited thereto, and the plurality of through holes TH may include a plurality of first through holes adjacent to the second transistor M2 and spaced apart from each other in the peripheral area PA, and a plurality of second through holes spaced apart from each other in the display area DA.

According to some embodiments, as the plurality of through holes TH are formed by penetrating the third interlayer insulating layer ILD3, at least a portion of an upper surface of the second buffer layer BUF2 may be exposed.

For example, the plurality of through holes TH may not overlap the first transistor M1 and the second transistor M2 in the plan view.

The plurality of through holes TH may be spaced apart from each other at a constant pitch PT along the first direction D1 and the second direction D2. According to some embodiments, the pitch PT between two adjacent through holes among the plurality of through holes TH may range from 10 micrometers (μm) to 15 micrometers (μm) (or about 10 micrometers (μm) to about 15 micrometers (μm)). In case that the pitch PT is less than 10 μm or more than 15 μm (or less than about 10 μm or more than about 15 μm), characteristics of the lower element included in the first circuit layer CRL1 may be deteriorated.

According to some embodiments, in the peripheral area PA, at least two through holes TH may be located in an area adjacent to the upper active pattern UAP. For example, in the plan view, a shortest distance IT between each of the plurality of through holes TH and the second lower gate electrode LGE2 may be 1.1 μm (or about 1.1 μm). For example, a size of each of the plurality of through holes TH may be 1.8 μm×1.8 μm (or about 1.8 μm×about 1.8 μm). The above-described numerical value of the shortest distance IT and the above-described numerical value of the size of each of the plurality of through holes TH may be optimal values to prevent or reduce deterioration of the characteristics of the lower element. However, the embodiments of the present disclosure are not necessarily limited thereto.

The first and second middle connection patterns MCP1 and MCP2, the third gate connection pattern GCP3, and the second conductive pattern CP2 may be located on the third interlayer insulating layer ILD3. The first middle connection pattern MCP1 and the first conductive pattern CP1 may be located in the display area DA, and the second middle connection pattern MCP2 and the third gate connection pattern GCP3 may be located in the peripheral area PA.

The first middle connection pattern MCP1 may be connected to the first lower connection pattern LCP1 through a contact hole penetrating the second interlayer insulating layer ILD2, the second buffer layer BUF2, and the third interlayer insulating layer ILD3. The second middle connection pattern MCP2 may be connected to the third lower connection pattern LCP3 through a contact hole penetrating the second interlayer insulating layer ILD2, the second buffer layer BUF2, and the third interlayer insulating layer ILD3, and may be connected to the sixth conductive region DR6 of the upper active pattern UAP through a contact hole penetrating the third interlayer insulating layer ILD3. In addition, the third gate connection pattern GCP3 may be connected to the fourth lower metal layer UBL2 through a contact hole penetrating the second buffer layer BUF2 and the third interlayer insulating layer ILD3, and may be connected to the upper gate electrode UGE through a contact hole penetrating the third interlayer insulating layer ILD3.

The second conductive pattern CP2 may overlap the first conductive pattern CP1 in the plan view. Accordingly, the second conductive pattern CP2 may form a first sub-capacitor with the first conductive pattern CP1, and the first conductive pattern CP1 may form a second sub-capacitor with the third lower metal layer UBL1. In addition, the third lower metal layer UBL1 may form a third sub-capacitor with a third conductive pattern located thereunder. The third conductive pattern may be electrically connected to the first conductive pattern CP1, and the third lower metal layer UBL1 may be electrically connected to the second conductive pattern CP2. In this case, the third conductive pattern may be located in the same layer as the first, second, and third lower connection patterns LAP1, LAP2, and LAP3. Accordingly, the first, second, and third sub-capacitors may form one capacitor CAP.

For example, the first and second middle connection patterns MCP1 and MCP2, the third gate connection pattern GCP3, and the second conductive pattern CP2 may include a metal, an alloy, a metal nitride, a conductive metal oxide, a transparent conductive material, and the like. These may be used alone or in combination with each other. Each of the first and second middle connection patterns MCP1 and MCP2, the third gate connection pattern GCP3, and the second conductive pattern CP2 may have a single-layer structure or a multi-layer structure in which a plurality of layers is stacked.

The first and second middle connection patterns MCP1 and MCP2, the third gate connection pattern GCP3, and the second conductive pattern CP2 may include the same material and may be located in the same layer. That is, the first and second middle connection patterns MCP1 and MCP2, the third gate connection pattern GCP3, and the second conductive pattern CP2 may be formed through the same process.

The first via insulating layer VIA1 may be located on the third interlayer insulating layer ILD3. The first via insulating layer VIA1 may be located in the display area DA and the peripheral area PA. The first via insulating layer VIA1 may have a substantially flat upper surface so as to sufficiently cover the first and second middle connection patterns MCP1 and MCP2 and the third gate connection pattern GCP3. For example, the first via insulating layer VIA1 may include an organic insulating material such as a photoresist, a polyacrylic resin, a polyimide resin, a polyamide resin, a siloxane resin, an acrylic resin, an epoxy resin, and the l like. These may be used alone or in combination with each other. The first via insulating layer VIA1 may have a single-layer structure or a multi-layer structure in which a plurality of layers is stacked.

According to some embodiments, the first via insulating layer VIA1 may fill interiors of the plurality of through holes TH. That is, an insulating material may be filled inside the plurality of through holes TH. In other words, a conductive material may not be filled in the interiors of the plurality of through holes TH.

The first upper connection pattern UAP1 and the second upper connection pattern UAP2 may be located on the first via insulating layer VIA1. The first upper connection pattern UAP1 may be located in the display area DA, and the second upper connection pattern UAP2 may be located in the peripheral area PA.

The first upper connection pattern UAP1 may be connected to the first middle connection pattern MCP1 through a contact hole penetrating the first via insulating layer VIA1. In addition, the second upper connection pattern UAP2 may be connected to the second middle connection pattern MCP2 through a contact hole penetrating the first via insulating layer VIA1.

For example, the first and second upper connection patterns UAP1 and UAP2 may include a metal, an alloy, a metal nitride, a conductive metal oxide, a transparent conductive material, and the like. These may be used alone or in combination with each other. Each of the first and second upper connection patterns UAP1 and UAP2 may have a single-layer structure or a multi-layer structure in which a plurality of layers is stacked.

The first and second upper connection patterns UAP1 and UAP2 may include the same material and may be located in the same layer. That is, the first and second upper connection patterns UAP1 and UAP2 may be formed through the same process.

The second via insulating layer VIA2 may be located on the first via insulating layer VIA1. The second via insulating layer VIA2 may be located in the display area DA and the peripheral area PA. The second via insulating layer VIA2 may have a substantially flat upper surface so as to sufficiently cover the first and second upper connection patterns UAP1 and UAP2. For example, the second via insulating layer VIA2 may include an organic insulating material such as a photoresist, a polyacrylic resin, a polyimide resin, a polyamide resin, a siloxane resin, an acrylic resin, an epoxy resin, and the like. These may be used alone or in combination with each other. The second via insulating layer VIA2 may have a single-layer structure or a multi-layer structure in which a plurality of layers is stacked.

The pixel electrode PE may be located in the display area DA on the second via insulating layer VIA2. The pixel electrode PE may be connected to the first upper connection pattern UAP1 through a contact hole penetrating the second via insulating layer VIA2. The pixel electrode PE may be a transmissive electrode, a semi-transmissive electrode, or a reflective electrode. For example, the pixel electrode PE may include a metal, an alloy, a metal nitride, a conductive metal oxide, a transparent conductive material, and the like. These may be used alone or in combination with each other. The pixel electrode PE may operate as an anode. The pixel electrode PE may have a single-layer structure or a multi-layer structure in which a plurality of layers is stacked.

The pixel defining layer PDL may be located in the display area DA on the second via insulating layer VIA2. A pixel opening exposing at least a portion of an upper surface of the pixel electrode PE may be defined in the pixel defining layer PDL. The pixel defining layer PDL may include an inorganic insulating material or an organic insulating material. For example, the pixel defining layer PDL may include an organic insulating material such as a photoresist, a polyacrylic resin, a polyimide resin, a polyamide resin, a siloxane resin, an acrylic resin, an epoxy resin, and the like. These may be used alone or in combination with each other. Alternatively, the pixel defining layer PDL may include an inorganic insulating material or an organic insulating material containing a light-blocking material such as a black pigment or a black dye.

The light-emitting layer EML may be located on the pixel electrode PE. Specifically, the light-emitting layer EML may be located inside the pixel opening of the pixel defining layer PDL. For example, the light-emitting layer EML may include an organic light-emitting material or an inorganic light-emitting material which generates preset light. A hole injection layer, a hole transport layer, an electron injection layer, an electron transport layer, and the like may be additionally arranged with the light-emitting layer EML in between.

The common electrode CME may be located on the second via insulating layer VIA2, the pixel defining layer PDL, and the light-emitting layer EML. The common electrode CME may be entirely located in the display area DA and may be located in at least a portion of the peripheral area PA.

The common electrode CME may be a transmissive electrode, a semi-transmissive electrode, or a reflective electrode. For example, the common electrode CME may include a metal, an alloy, a metal nitride, a conductive metal oxide, a transparent conductive material, and the like. These may be used alone or in combination with each other. The common electrode CME may operate as a cathode. The common electrode CME may have a single-layer structure or a multi-layer structure in which a plurality of layers is stacked.

Accordingly, the light-emitting element LED including the pixel electrode PE, the light-emitting layer EML, and the common electrode CME may be formed in the display area DA.

The encapsulation layer may be additionally located on the common electrode CME. The encapsulation layer may be located in the display area DA and the peripheral area PA, and may include at least one inorganic layer and at least one organic layer. The inorganic layer of the encapsulation layer may protect the light-emitting element LED from external moisture, and the organic layer of the encapsulation layer may prevent or reduce damage to the light-emitting element LED due to contaminants or foreign substances introduced during the manufacturing process.

As described above, the first circuit layer CRL1 may include the first transistor M1 located in the peripheral area PA and including a metal oxide semiconductor, and the second circuit layer CRL2 located on the first circuit layer CRL1 may include the second transistor M2 located in the peripheral area PA and including a metal oxide semiconductor. That is, in the peripheral area PA, the first transistor M1 and the second transistor M2 may have a stacked structure along a thickness direction (e.g., the third direction D3). Accordingly, a dead space of the display device DD may be relatively reduced.

In a manufacturing process of the display device DD, hydrogen generated in insulating layers included in the first circuit layer CRL1 may be absorbed into lower active patterns (e.g., the first lower active pattern LAP1 and/or the second lower active pattern LAP2) and may act as carriers. Meanwhile, in the peripheral area PA, in a stacked structure in which the first transistor M1 and the second transistor M2 are stacked along the thickness direction, an amount of hydrogen absorbed by the lower active pattern may be relatively excessive. In this case, characteristics of a lower element included in the first circuit layer CRL1 (e.g., the first transistor M1 and/or the transistor TR) may be deteriorated, and variation of the lower element may increase.

In the display device DD according to some embodiments of the present disclosure, in the peripheral area PA, in a structure in which the first transistor M1 of the first circuit layer CRL1 including a metal oxide semiconductor and the second transistor M2 of the second circuit layer CRL2 including a metal oxide semiconductor are stacked along the thickness direction, the plurality of through holes TH spaced apart from each other may be defined in an inorganic insulating layer included in the second circuit layer CRL2 (i.e., the third interlayer insulating layer ILD3). Accordingly, through the plurality of through holes TH, hydrogen, which may be generated in insulating layers included in the first circuit layer CRL1 and absorbed into the lower active pattern of the first transistor M1 and act as carriers, may diffuse (or be discharged) to the outside (i.e., to the second circuit layer CRL2). In this case, characteristics of the lower element included in the first circuit layer CRL1 may not be deteriorated, and variation of the lower element may be relatively reduced.

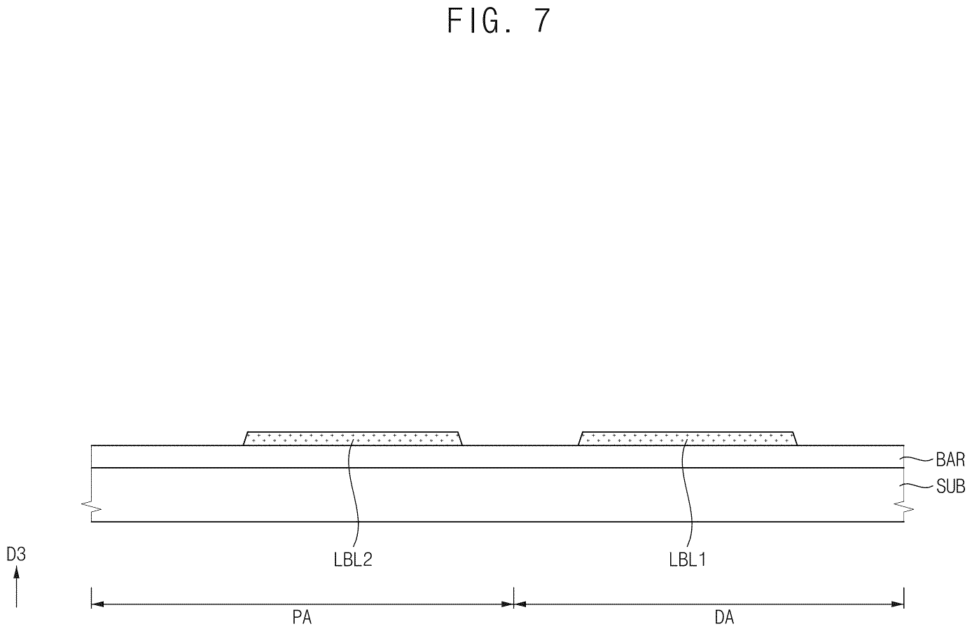

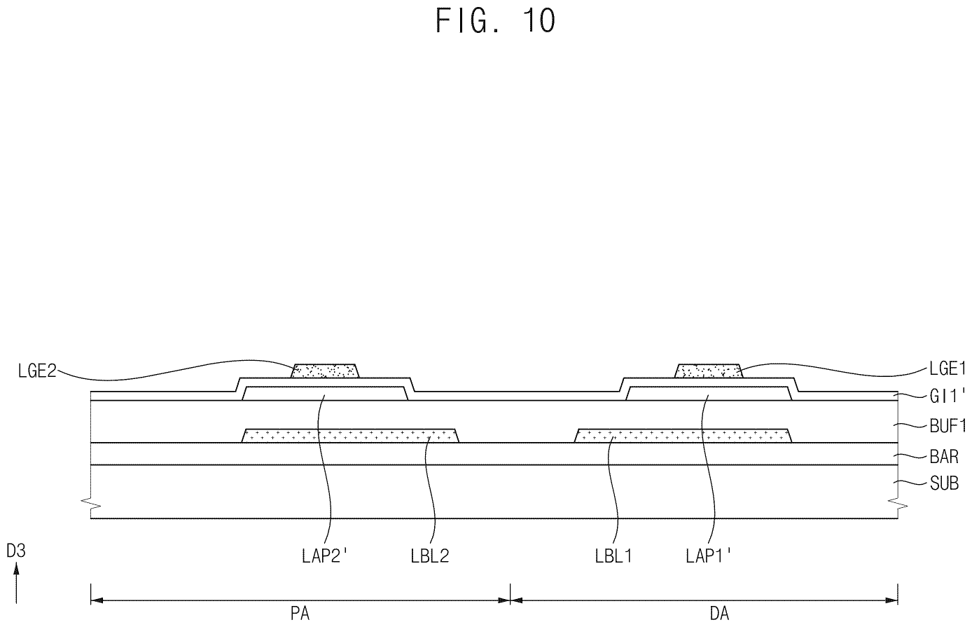

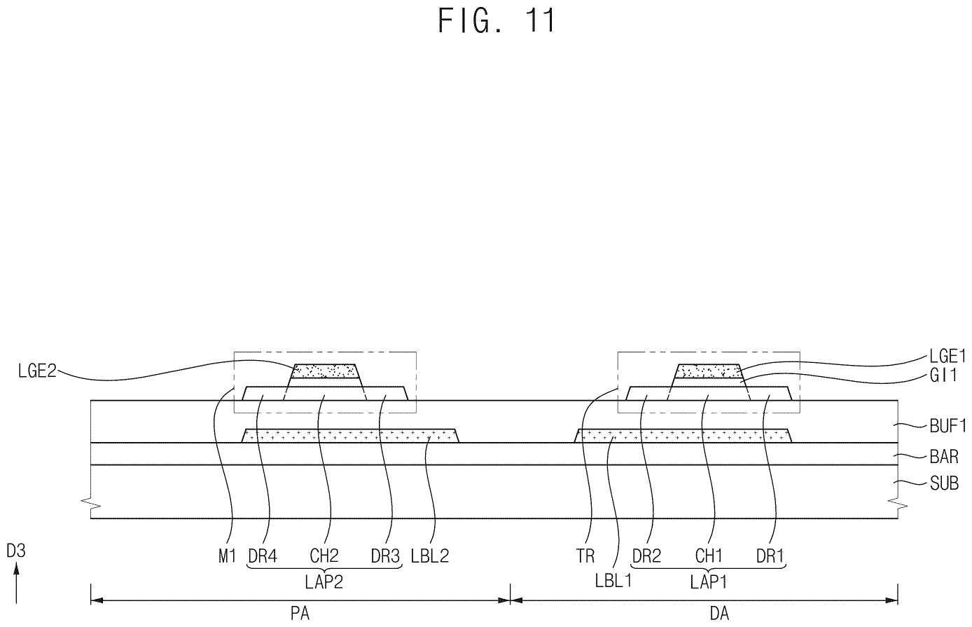

FIGS. 7 to 20 are cross-sectional views for explaining a method for manufacturing the display device of FIG. 4. In the following, any content that overlaps with the content of the display device DD described with reference to FIG. 4 is omitted or simplified.

Referring to FIG. 7, the barrier layer BAR may be formed in the display area DA and the peripheral area PA on the substrate SUB. For example, the barrier layer BAR may include an inorganic insulating material.

The first and second lower metal layers LBL1 and LBL2 may be formed on the barrier layer BAR. The first lower metal layer LBL1 may be formed in the display area DA, and the second lower metal layer LBL2 may be formed in the peripheral area PA.

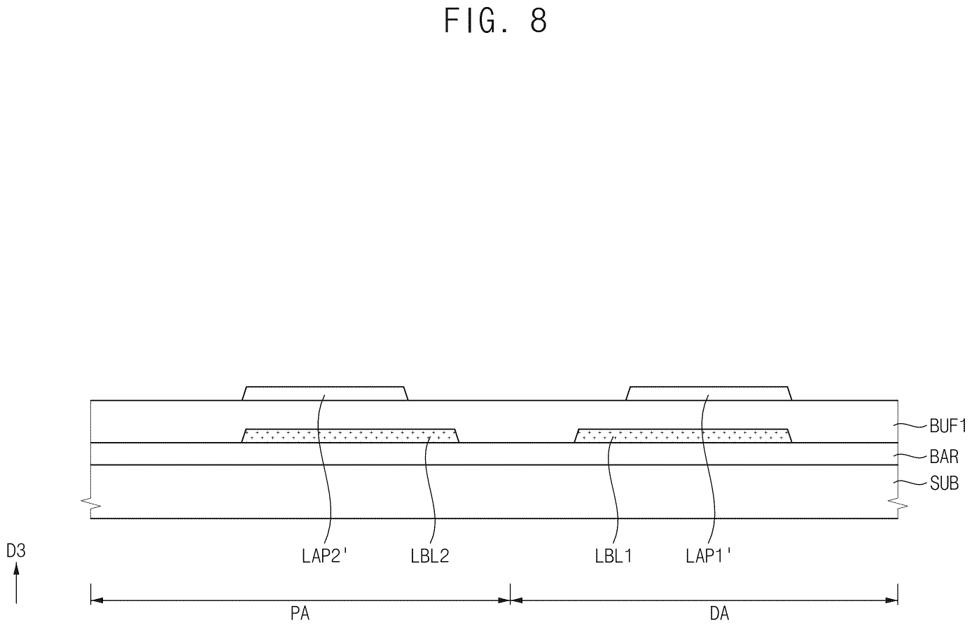

Referring to FIG. 8, the first buffer layer BUF1 may be formed in the display area DA and the peripheral area PA on the barrier layer BAR. The first buffer layer BUF1 may be formed to cover the first and second lower metal layers LBL1 and LBL2. For example, the first buffer layer BUF1 may include an inorganic insulating material.

A first lower active pattern LAP1′ and a second lower active pattern LAP2′ may be formed on the first buffer layer BUF1. The first lower active pattern LAP1′ may be formed in the display area DA, and the second lower active pattern LAP2′ may be formed in the peripheral area PA. According to some embodiments, the first and second lower active patterns LAP1′ and LAP2′ may include a metal oxide semiconductor.

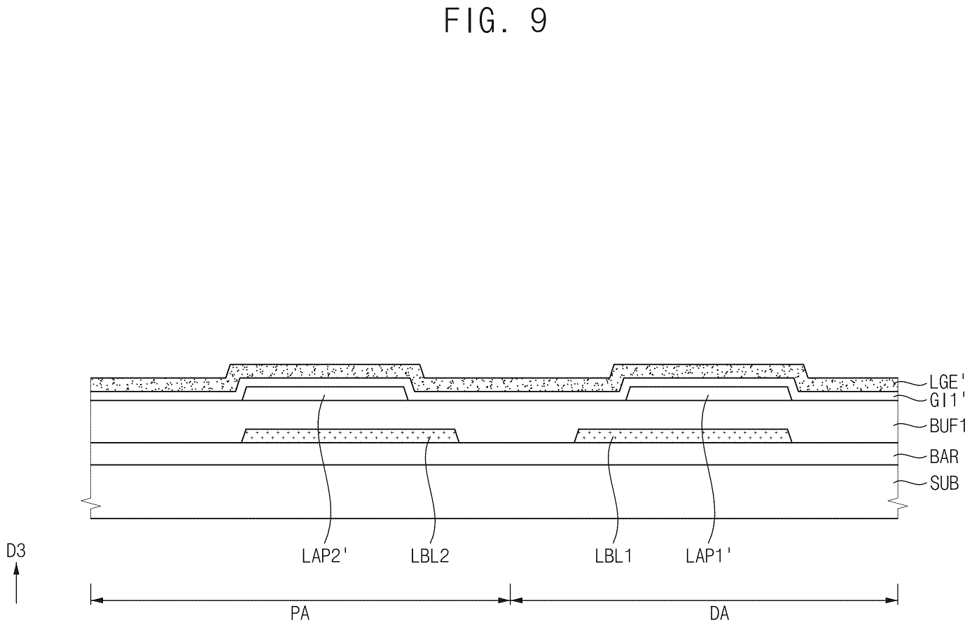

Referring to FIGS. 9 to 11, a preliminary first gate insulating layer GI1′ may be formed in the display area DA and the peripheral area PA on the first buffer layer BUF1. The preliminary first gate insulating layer GI1′ may be formed to cover the first and second lower active patterns LAP1′ and LAP2′. For example, the preliminary first gate insulating layer GI1′ may include an inorganic insulating material.

A gate electrode layer LGE′ may be formed in the display area DA and the peripheral area PA on the preliminary first gate insulating layer GI1′.

A first photosensitive organic pattern and a second photosensitive organic pattern may be formed on the gate electrode layer LGE′. The first photosensitive organic pattern may correspond to an area where the first lower gate electrode LGE1 is to be formed, and the second photosensitive organic pattern may correspond to an area where the second lower gate electrode LGE2 is to be formed. For example, the first and second photosensitive organic patterns may include a positive photoresist or a negative photoresist.

Through a first etching process, a portion of the gate electrode layer LGE′ may be removed using the first and second photosensitive organic patterns as masks. Specifically, through the first etching process, portions of the gate electrode layer LGE′ which do not overlap the first and second photosensitive organic patterns may be removed. Accordingly, the first lower gate electrode LGE1 may be formed in an area corresponding to the first photosensitive organic pattern, and the second lower gate electrode LGE2 may be formed in an area corresponding to the second photosensitive organic pattern.

After the first and second lower gate electrodes LGE1 and LGE2 are formed, through a second etching process, a portion of the preliminary first gate insulating layer GI1′ may be removed using the first and second photosensitive organic patterns as masks. Specifically, through the second etching process, portions of the preliminary first gate insulating layer GI1′ which do not overlap the first and second photosensitive organic patterns may be removed. Accordingly, the first gate insulating layer GI1 may be formed in a patterned form in an area corresponding to each of the first and second photosensitive organic patterns.

During removal of a portion of the preliminary first gate insulating layer GI1′ through the second etching process, hydrogen included in the preliminary first gate insulating layer GI1′ may flow into the first and second lower active patterns LAP1′ and LAP2′. The portion of the first lower active pattern LAP1′ into which the hydrogen is introduced has a carrier concentration increased by the introduced hydrogen, thereby having conductivity, and thus may become the first conductive region DR1 and the second conductive region DR2. Accordingly, the first lower active pattern LAP1 including the first conductive region DR1, the second conductive region DR2, and the first channel region CH1 may be formed.

Similarly, the portion of the second lower active pattern LAP2′ into which the hydrogen is introduced has a carrier concentration increased by the introduced hydrogen, thereby becoming conductive, and thus may become the third conductive region DR3 and the fourth conductive region DR4. Accordingly, the second lower active pattern LAP2 including the third conductive region DR3, the fourth conductive region DR4, and the second channel region CH2 may be formed.

Accordingly, the transistor TR including the first lower active pattern LAP1 and the first lower gate electrode LGE1 may be formed in the display area DA, and the first transistor M1 including the second lower active pattern LAP2 and the second lower gate electrode LGE2 may be formed in the peripheral area PA.

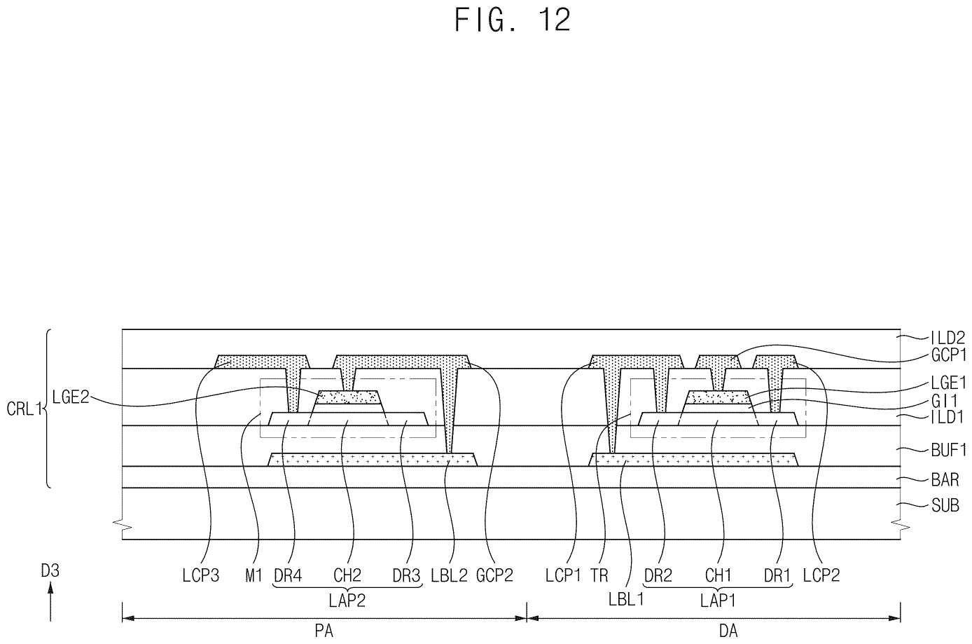

Referring to FIG. 12, the first interlayer insulating layer ILD1 may be formed in the display area DA and the peripheral area PA on the first buffer layer BUF1. The first interlayer insulating layer ILD1 may be formed to cover the transistor TR and the first transistor M1. For example, the first interlayer insulating layer ILD1 may include an inorganic insulating material.

A first contact hole exposing the first conductive region DR1, a second contact hole exposing the second conductive region DR2, a third contact hole exposing the fourth conductive region DR4, a fourth contact hole exposing the first lower gate electrode LGE1, and a fifth contact hole exposing the second lower gate electrode LGE2 may be formed by penetrating the first interlayer insulating layer ILD1. At the same time, a sixth contact hole exposing the first lower metal layer LBL1 and a seventh contact hole exposing the second lower metal layer LBL2 may be formed by penetrating the first buffer layer BUF1 and the first interlayer insulating layer ILD1.

Next, a conductive layer may be entirely formed on the first interlayer insulating layer ILD1 to fill interiors of the first, second, third, fourth, fifth, sixth, and seventh contact holes. By etching the conductive layer, the first lower connection pattern LCP1 respectively connected to the second conductive region DR2 and the first lower metal layer LBL1 through the first and sixth contact holes, the second lower connection pattern LCP2 connected to the first conductive region DR1 through the second contact hole, the third lower connection pattern LCP3 connected to the fourth conductive region DR4 through the third contact hole, the first gate connection pattern GCP1 connected to the first lower gate electrode LGE1 through the fourth contact hole, and the second gate connection pattern GCP2 respectively connected to the second lower gate electrode LGE2 and the second lower metal layer LBL2 through the fifth and seventh contact holes may be formed.

The second interlayer insulating layer ILD2 may be formed in the display area DA and the peripheral area PA on the first interlayer insulating layer ILD1. The second interlayer insulating layer ILD2 may be formed while covering the first, second, and third lower connection patterns LCP1, LCP2, and LCP3 and the first and second gate connection patterns GCP1 and GCP2. For example, the second interlayer insulating layer ILD2 may include an inorganic insulating material.

Accordingly, the first circuit layer CRL1 including the barrier layer BAR, the first and second lower metal layers LBL1 and LBL2, the first buffer layer BUF1, the transistor TR, the first transistor M1, the first gate insulating layer GI1, the first interlayer insulating layer ILD1, the first, second, and third lower connection patterns LCP1, LCP2, and LCP3, the first and second gate connection patterns GCP1 and GCP2, and the second interlayer insulating layer ILD2 may be formed.

Referring to FIG. 13, the third and fourth lower metal layers UBL1 and UBL2 may be formed on the second interlayer insulating layer ILD2. The third lower metal layer UBL1 may be formed in the display area DA, and the fourth lower metal layer UBL2 may be formed in the peripheral area PA.

The second buffer layer BUF2 may be formed in the display area DA and the peripheral area PA on the second interlayer insulating layer ILD2. The second buffer layer BUF2 may be formed to cover the third and fourth lower metal layers UBL1 and UBL2. For example, the second buffer layer BUF2 may include an inorganic insulating material.

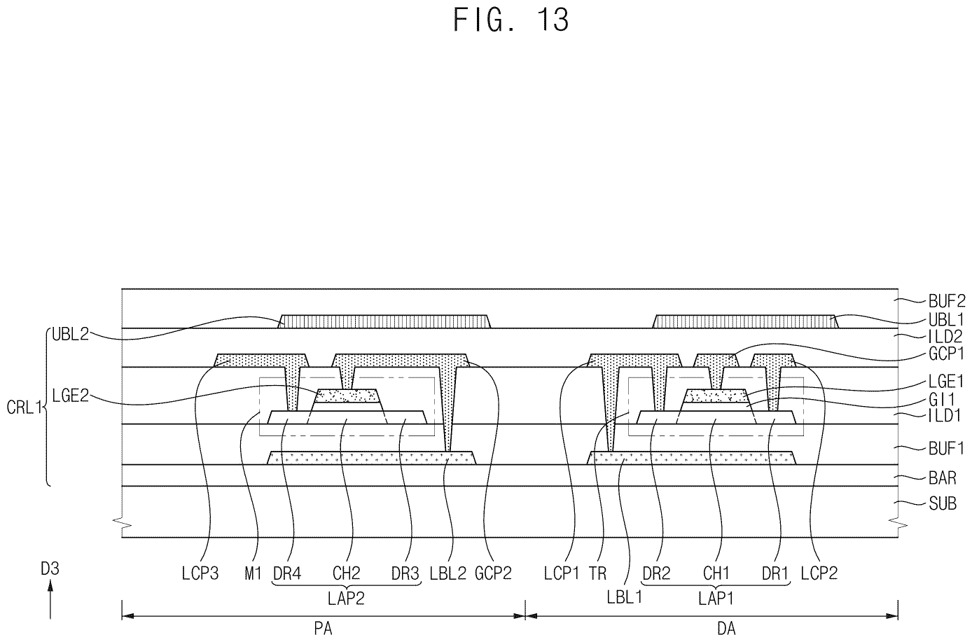

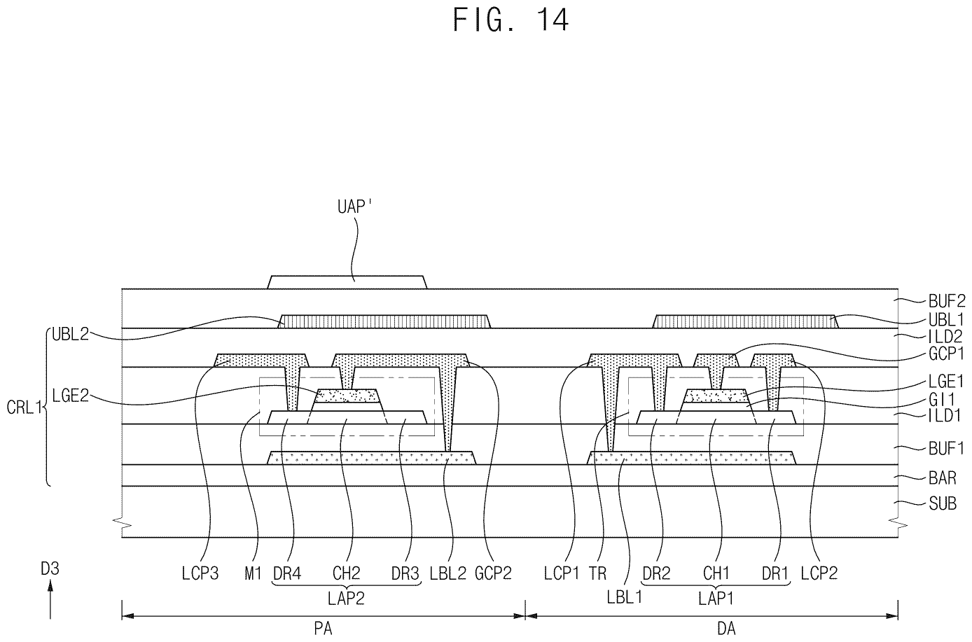

Referring to FIGS. 14 and 15, the upper active pattern UAP′ may be formed in the peripheral area PA on the second buffer layer BUF2. According to some embodiments, the upper active pattern UAP′ may include a metal oxide semiconductor.

Using a photosensitive organic pattern as a mask, the upper gate electrode UGE overlapping the upper active pattern UAP in the plan view and the first conductive pattern CP1 overlapping the third lower metal layer UBL1 in the plan view may be formed. Accordingly, the first conductive pattern CP1 may form one sub-capacitor of the capacitor CAP together with the third lower metal layer UBL1.

Next, using the photosensitive organic pattern as a mask, the second gate insulating layer GI2 may be formed in a patterned form under each of the upper gate electrode UGE and the first conductive pattern CP1.

During formation of the second gate insulating layer GI2, hydrogen included in the second gate insulating layer GI2 may flow into the upper active pattern UAP′. The portion of the upper active pattern UAP′ into which the hydrogen is introduced has a carrier concentration increased by the introduced hydrogen, thereby becoming conductive, and thus may become the fifth conductive region DR5 and the sixth conductive region DR6. Accordingly, the upper active pattern UAP including the fifth conductive region DR5, the sixth conductive region DR6, and the third channel region CH3 may be formed.

Accordingly, the second transistor M2 including the upper active pattern UAP and the upper gate electrode UGE may be formed in the peripheral area PA.

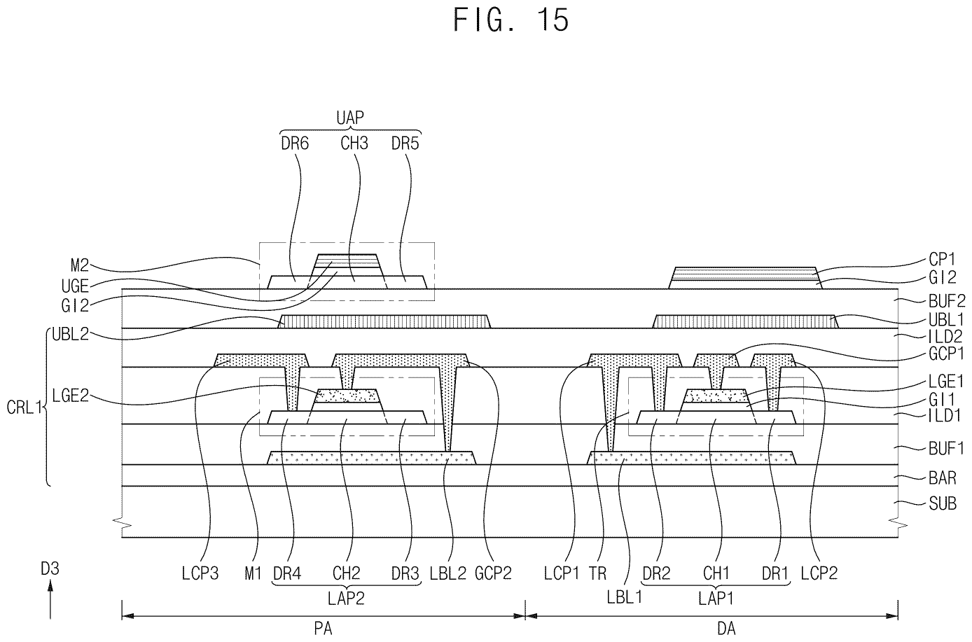

Referring to FIG. 16, the third interlayer insulating layer ILD3 may be formed in the display area DA and the peripheral area PA on the second buffer layer BUF2. The third interlayer insulating layer ILD3 may be formed to cover the second transistor M2 and the first conductive pattern CP1. For example, the third interlayer insulating layer ILD3 may include an inorganic insulating material.

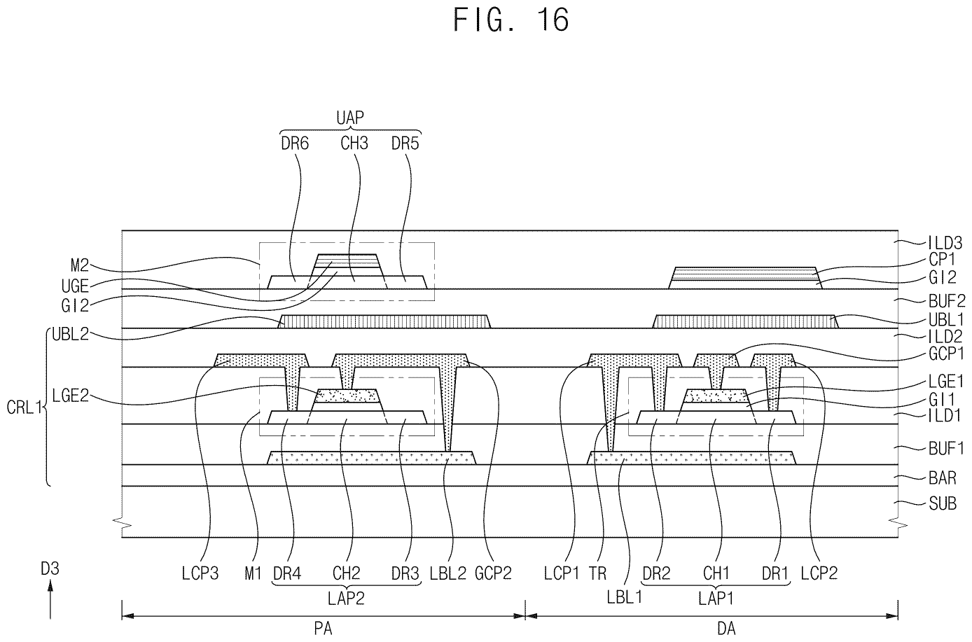

Referring to FIG. 17, through a third etching process, a first contact hole CNT1 exposing the first lower connection pattern LCP1 and a third contact hole CNT3 exposing the third lower connection pattern LCP3 may be formed by penetrating the second interlayer insulating layer ILD2, the second buffer layer BUF2, and the third interlayer insulating layer ILD3. In addition, through the third etching process, a second contact hole CNT2 exposing the fourth lower metal layer UBL2 may be formed by penetrating the second buffer layer BUF2 and the third interlayer insulating layer ILD3. That is, the first, second, and third contact holes CNT1, CNT2, and CNT3 may be simultaneously formed through the same process.

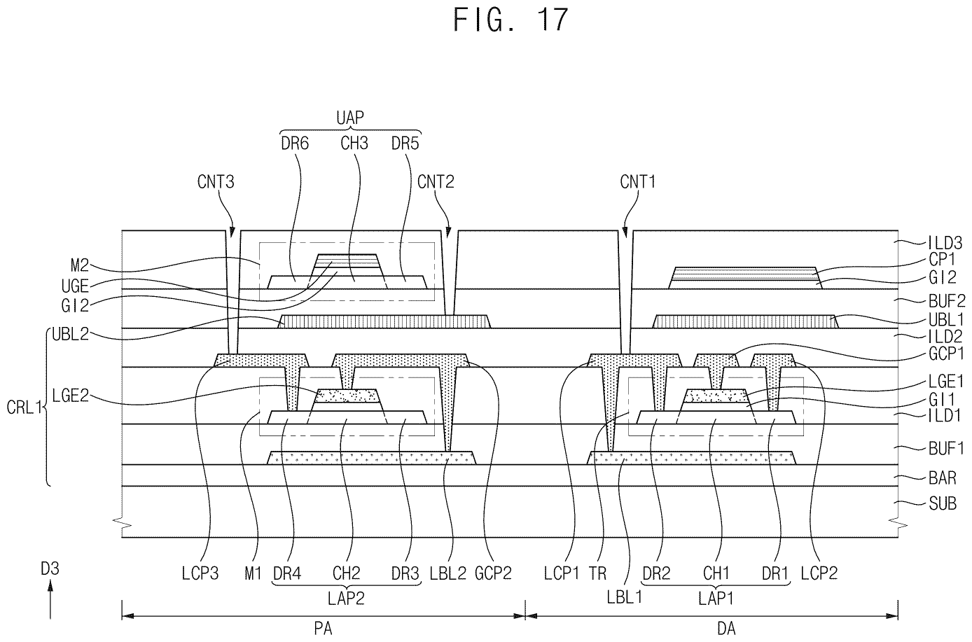

Referring to FIG. 18, through a fourth etching process, a fifth contact hole CNT5 exposing the upper gate electrode UGE and a sixth contact hole CNT6 exposing the sixth conductive region DR6 may be formed by penetrating the third interlayer insulating layer ILD3. According to some embodiments, through the fourth etching process, the plurality of through holes TH exposing the second buffer layer BUF2 may be formed by penetrating the third interlayer insulating layer ILD3. That is, the plurality of through holes TH, the fifth contact hole CNT5, and the sixth contact hole CNT6 may be simultaneously formed through the same process.

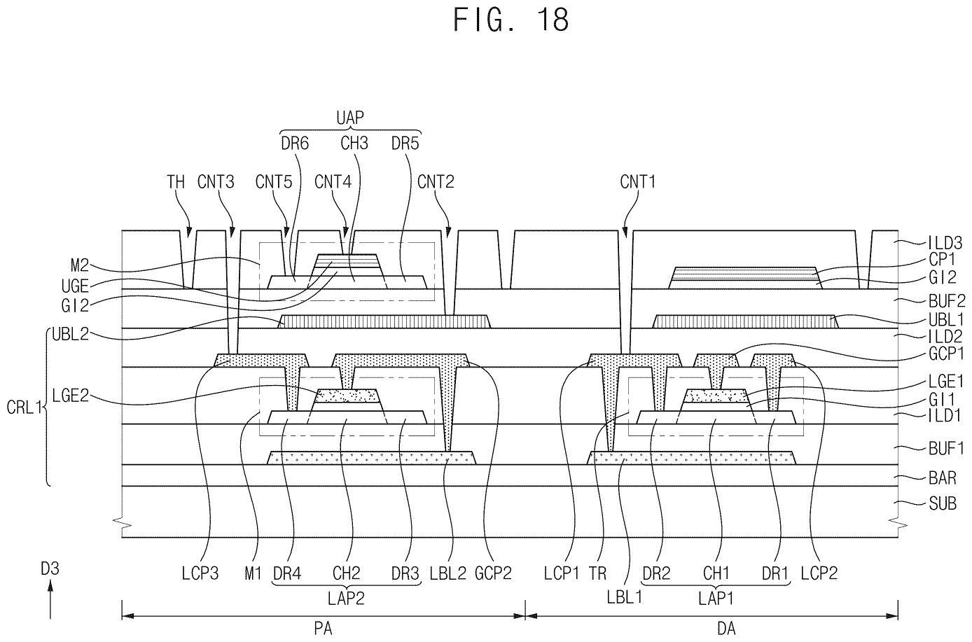

Referring to FIG. 19, a conductive layer may be entirely formed on the third interlayer insulating layer ILD3. By etching the conductive layer, the first middle connection pattern MCP1 connected to the first lower connection pattern LCP1 through the first contact hole CNT1, the third gate connection pattern GCP3 and the second middle connection pattern MCP2 respectively connected to the fourth lower metal layer UBL2 and the upper gate electrode UGE through second and fourth contact holes CNT2 and CNT4, and respectively connected to the third lower connection pattern LCP3 and the sixth conductive region DR6 through third and fifth contact holes CNT3 and CNT5 may be formed. In addition, by etching the conductive layer, the second conductive pattern CP2 overlapping the first conductive pattern CP1 in the plan view may be formed. That is, the second conductive pattern CP2, the first and second middle connection patterns MCP1 and MCP2, and the third gate connection pattern GCP3 may be simultaneously formed through the same process.

Accordingly, the second conductive pattern CP2 may form one sub-capacitor of the capacitor CAP together with the first conductive pattern CP1.

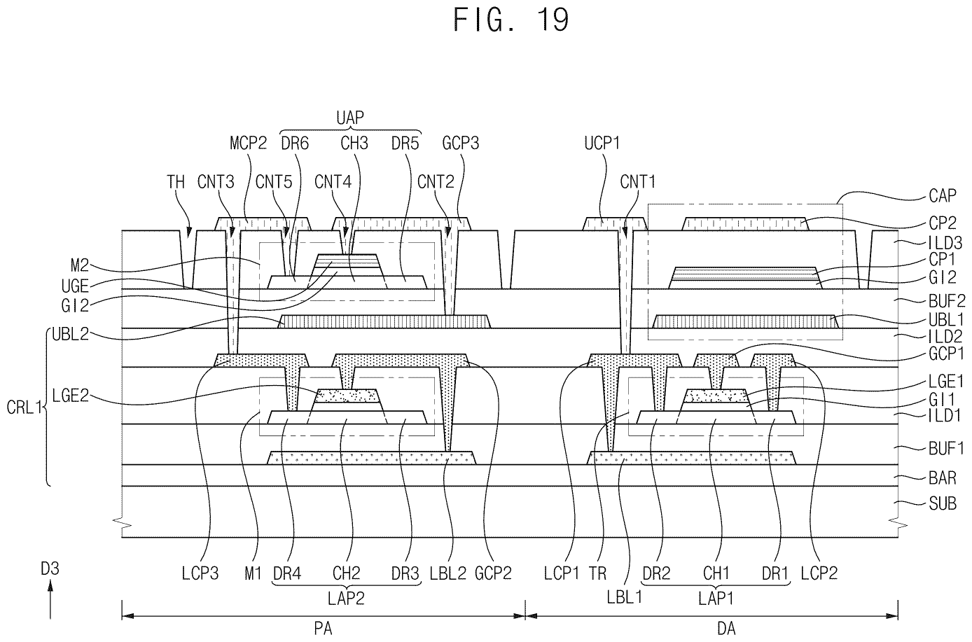

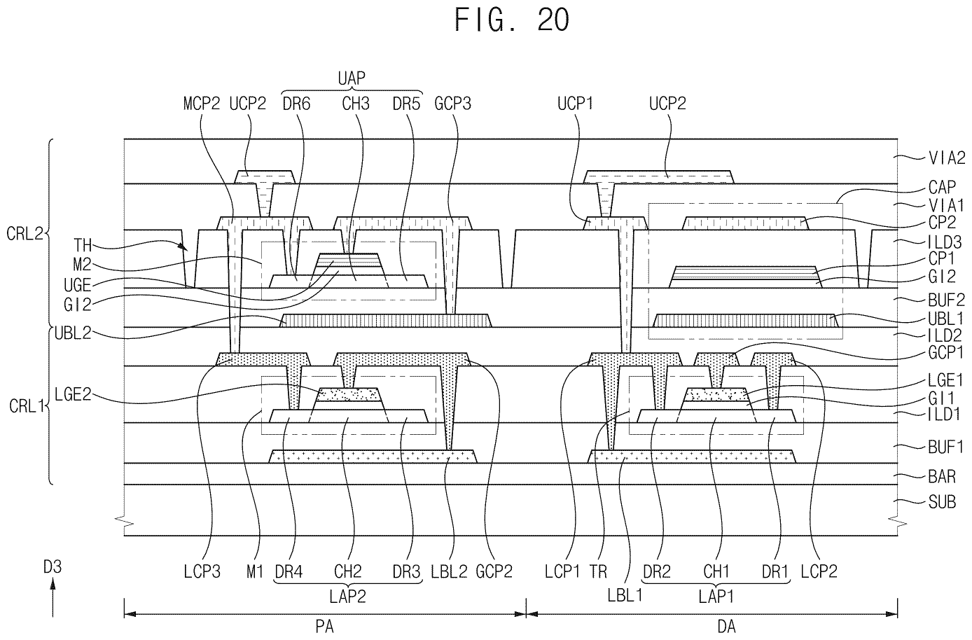

Referring to FIG. 20, the first via insulating layer VIA1 may be formed in the display area DA and the peripheral area PA on the third interlayer insulating layer ILD3. The first via insulating layer VIA1 may sufficiently cover the first and second middle connection patterns MCP1 and MCP2 and the third gate connection pattern GCP3. For example, the first via insulating layer VIA1 may include an organic insulating material.

A first contact hole exposing the first middle connection pattern MCP1 and a second contact hole exposing the second middle connection pattern MCP2 may be formed by penetrating the first via insulating layer VIA1. Next, a conductive layer may be entirely formed on the first via insulating layer VIA1 to fill the first and second contact holes. By etching the conductive layer, the first upper connection pattern UCP1 connected to the first middle connection pattern MCP1 through the first contact hole and the second upper connection pattern UCP2 connected to the second middle connection pattern MCP2 through the second contact hole may be formed.

The second via insulating layer VIA2 may be formed in the display area DA and the peripheral area PA on the first via insulating layer VIA1. The second via insulating layer VIA2 may be formed to sufficiently cover the first and second upper connection patterns UCP1 and UCP2. For example, the second via insulating layer VIA2 may include an organic insulating material.

Accordingly, the second circuit layer CRL2 including the third and fourth lower metal layers UBL1 and UBL2, the second buffer layer BUF2, the second transistor M2, the second gate insulating layer GI2, the first conductive pattern CP1, the third interlayer insulating layer ILD3, the second conductive pattern CP2, the first and second middle connection patterns MCP1 and MCP2, the third gate connection pattern GCP3, the first via insulating layer VIA1, the first and second upper connection patterns UCP1 and UCP2, and the second via insulating layer VIA2 may be formed on the first circuit layer CRL1.

Referring back to FIG. 4, the pixel electrode PE may be formed in the display area DA on the second via insulating layer VIA2. The pixel electrode PE may be connected to the first upper connection pattern UCP1 through a contact hole penetrating the second via insulating layer VIA2.

The pixel defining layer PDL may be formed in the display area DA on the second via insulating layer VIA2. A pixel opening exposing at least a portion of an upper surface of the pixel electrode PE may be defined in the pixel defining layer PDL. For example, the pixel defining layer PDL may include an inorganic insulating material or an organic insulating material.

The light-emitting layer EML may be formed on the pixel electrode PE. Specifically, the light-emitting layer EML may be formed inside the pixel opening of the pixel defining layer PDL. The common electrode CME may be formed on the second via insulating layer VIA2, the pixel defining layer PDL, and the light-emitting layer EML. Accordingly, a light-emitting element LED including the pixel electrode PE, the light-emitting layer EML, and the common electrode CME may be formed in the display area DA.

Accordingly, the display device DD illustrated in FIG. 4 may be manufactured.

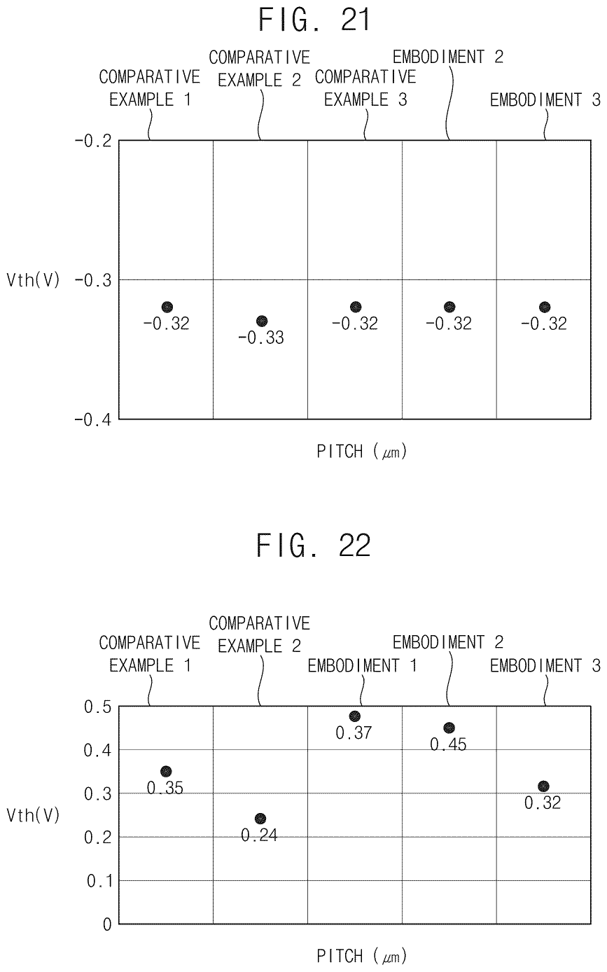

FIG. 21 is a graph for explaining a change in a threshold voltage (Vth) of an upper element according to a pitch between through holes in comparative examples and embodiments. FIG. 22 is a graph for explaining a change in a threshold voltage (Vth) of a lower element according to the pitch between through holes in comparative examples and embodiments. Here, the upper element refers to the second transistor M2 of FIG. 4, and the lower element refers to the first transistor M1 of FIG. 4.

Referring to FIGS. 4, 21, and 22, in Comparative Example 1, the through holes TH were not formed in the third interlayer insulating layer ILD3. In Comparative Example 2, the through holes TH spaced apart from each other with a pitch of 5 micrometers (μm) (or about 5 micrometers (μm)) were formed in the third interlayer insulating layer ILD3. In Comparative Example 3, the through holes TH spaced apart from each other with a pitch PT of 20 micrometers (μm) (or about 20 micrometers (μm)) were formed in the third interlayer insulating layer ILD3. In Embodiment 1, the through holes TH spaced apart from each other with a pitch PT of 10 micrometers (μm) (or about 10 micrometers (μm)) were formed in the third interlayer insulating layer ILD3. In Embodiment 2, the through holes TH spaced apart from each other with a pitch PT of 15 micrometers (μm) (or about 15 micrometers (μm)) were formed in the third interlayer insulating layer ILD3.

As a result, as illustrated in FIG. 21, it can be confirmed that the threshold voltage (Vth) of the upper element is substantially the same or similar in Embodiments 1 and 2 and Comparative Examples 1, 2, and 3. Through this, it can be confirmed that even if the through holes TH are formed in the third interlayer insulating layer ILD3, the characteristics of the upper element are not affected.

As a result, as illustrated in FIG. 22, it can be confirmed that the threshold voltage (Vth) of the lower element in Embodiments 1 and 2 is greater than the threshold voltage (Vth) of the lower element in Comparative Examples 1, 2, and 3. Through this, in case that the through holes TH are formed in the third interlayer insulating layer ILD3 to be spaced apart from each other at a pitch PT of 10 micrometers (μm) or more and 15 micrometers (μm) or less (or about 10 micrometers (μm) or more and about 15 micrometers (μm) or less) as in Embodiments 1 and 2, it can be confirmed that the threshold voltage (Vth) of the lower element is positively shifted compared to Comparative Examples 1, 2, and 3. That is, it can be confirmed that, in the case of satisfying Embodiments 1 and 2, the characteristics of the lower element are not deteriorated.

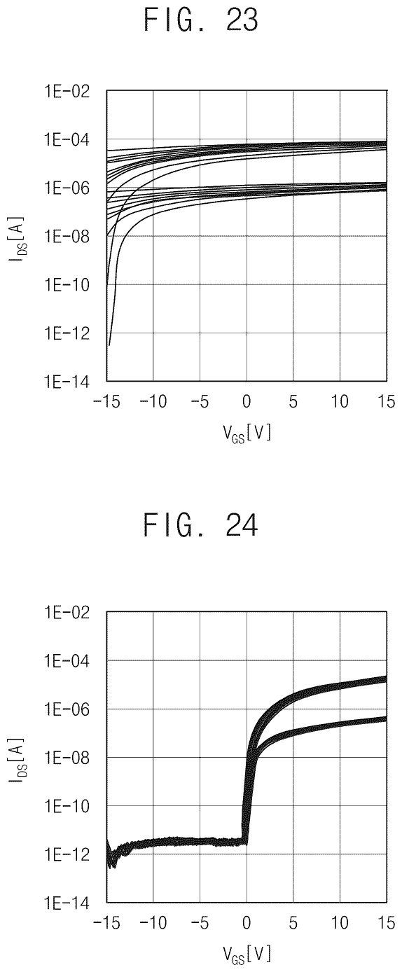

FIG. 23 is a graph for explaining a change in a drain-source current (Ids) according to a gate-source voltage (Vgs) of a lower element in a comparative example. FIG. 24 is a graph for explaining a change in a drain-source current (Ids) according to a gate-source voltage (Vgs) of a lower element according to some embodiments. Here, the lower element refers to the first transistor M1 of FIG. 4.

FIG. 23 illustrates Comparative Example in which the through holes TH are not formed in the third interlayer insulating layer ILD3. A plurality of lines illustrated in the graph of FIG. 23 correspond to lower elements arbitrarily selected among the lower elements located in the peripheral area PA.

FIG. 24 illustrates an Embodiment in which the through holes TH are formed in the third interlayer insulating layer ILD3 so as to be spaced apart from each other with the pitch PT of 10 micrometers (μm) to 15 micrometers (μm) (or about 10 micrometers (μm) to about 15 micrometers (μm)). A plurality of lines illustrated in the graph of FIG. 24 correspond to lower elements arbitrarily selected among the lower elements located in the peripheral area PA.

As a result, it can be confirmed that the threshold voltage (Vth) of the lower element is relatively excessively negatively shifted in Comparative Example. In addition, it can be confirmed that the threshold voltage (Vth) of the lower element in Embodiment is relatively positively shifted compared to Comparative Example. Through this, it can be confirmed that the characteristics of the lower element are not deteriorated in case that Embodiment is satisfied.

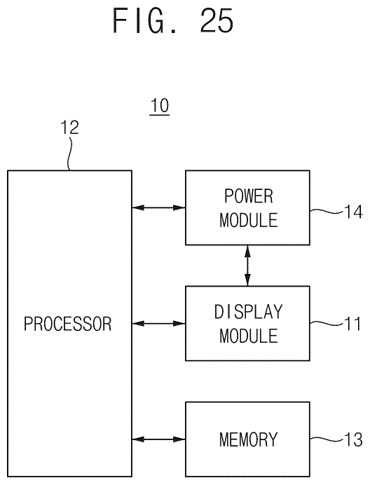

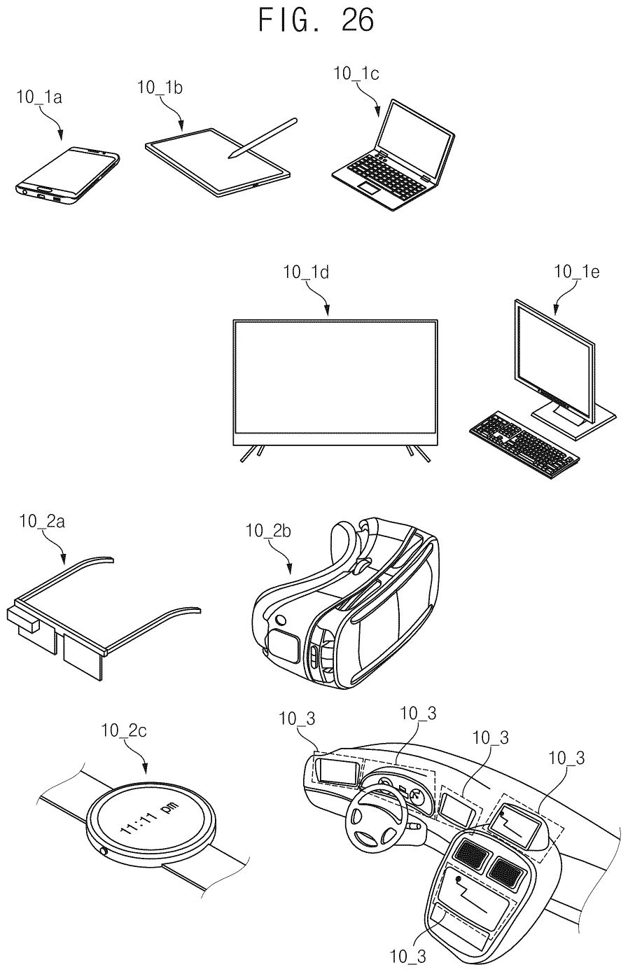

FIG. 25 is a block diagram illustrating an electronic device according to some embodiments of the present disclosure.

Referring to FIG. 25, an electronic device 10 according to some embodiments of the present disclosure may include a display module 11, a processor 12, a memory 13, and a power module 14.

The display device (e.g., the display device DD of FIG. 1) according to some embodiments of the present disclosure may be applied to various electronic devices. The electronic device 10 may include the display device, and in addition to the display device, may further include a module or device having other additional functions.

The processor 12 may include at least one of a central processing unit (CPU), an application processor (AP), a graphic processing unit (GPU), a communication processor (CP), an image signal processor (ISP), or a controller.

The memory 13 may store data information necessary for operation of the processor 12 or the display module 11. In case that the processor 12 executes an application stored in the memory 13, image data signals and/or input control signals may be transmitted to the display module 11, and the display module 11 may process the provided signals to output image information through a display screen.

The power module 14 may include a power supply module such as a power adapter or a battery device, and a power conversion module which converts power supplied by the power supply module to generate power necessary for operation of the electronic device 10.

At least one of the components of the electronic device 10 described above may be included in the display device according to the embodiments described above. In addition, some of the individual modules functionally included in one module may be included in the display device, and other parts may be provided separately from the display device. For example, the display device may include the display module 11, and the processor 12, the memory 13, and the power module 14 may be provided in the form of other devices within the electronic device 10 other than the display device.

FIG. 26 is a schematic diagram illustrating an electronic device according to various embodiments.

Referring to FIGS. 25 and 26, various electronic devices 10 to which the display device according to some embodiments is applied may include not only image display electronic devices such as a smartphone 10_1a, a tablet PC 10_1b, a laptop 10_1c, a TV 10_1d, and a desktop monitor 10_1e, but also wearable electronic devices including a display module such as smart glasses 10_2a, a head-mounted display 10_2b, and a smartwatch 10_2c, as well as vehicle electronic devices 10_3 including a display module such as a CID (Center Information Display) located in an instrument panel, a center fascia, or a dashboard of a vehicle, and a room mirror display.

As described above, while aspects of some embodiments of the present disclosure have been explained with reference to aspects of some embodiments, it will be understood by those of ordinary skill in the art that various modifications and changes can be made thereto without departing from the spirit and scope of the present disclosure as defined in the following claims, and their equivalents.

Aspects of some embodiments according to the present disclosure may be applied to various display device which can be equipped with a display device. For example, the present disclosure may be applied to high-resolution smartphones, mobile phones, smart pads, smart watches, tablet PCs, vehicle navigation systems, televisions, computer monitors, and notebook computers.

What is claimed is:

1. A display device comprising:
a substate including a display area and a peripheral area surrounding at least a portion of the display area;
a plurality of sub-pixels in the display area on the substrate;
a first transistor of a gate driver in the peripheral area on the substrate;
a second transistor of the gate driver in the peripheral area on the first transistor; and
an inorganic insulating layer covering the second transistor and defining a plurality of through holes adjacent to the second transistor and spaced apart from each other.

2. The display device of claim 1, wherein an insulating material is filled inside the plurality of through holes.

3. The display device of claim 1, further comprising:
a via insulating layer on the inorganic insulating layer, filling interiors of the plurality of through holes, and including an organic material.

4. The display device of claim 1, wherein the first transistor and the second transistor include a metal oxide semiconductor.

5. The display device of claim 1, wherein the second transistor includes:
an upper active pattern including a metal oxide semiconductor; and
an upper gate electrode overlapping a channel region of the upper active pattern in a plan view.

6. The display device of claim 5, further comprising:
a middle connection pattern connected to a conductive region of the upper active pattern through a contact hole penetrating the inorganic insulating layer in the peripheral area.

7. The display device of claim 1, further comprising:
a first interlayer insulating layer covering the first transistor;
a second interlayer insulating layer on the first interlayer insulating; and
a buffer layer between the second interlayer insulating layer and the second transistor,
wherein each of the plurality of through holes exposes at least a portion of the buffer layer.

8. The display device of claim 1, wherein a pitch between two adjacent through holes among the plurality of through holes is in a range of 10 micrometers (μm) or more and 15 micrometers (μm) or less.

9. The display device of claim 1, wherein the plurality of through holes include:
a plurality of first through holes adjacent to the second transistor and spaced apart from each other in the peripheral area; and
a plurality of second through holes spaced apart from each other in the display area.

10. The display device of claim 1, wherein each of the plurality of sub-pixels includes a plurality of transistors including a metal oxide semiconductor.

11. The display device of claim 10, wherein each of the plurality of transistors includes a first lower active pattern and the first transistor includes a second lower active pattern in a same layer as the first lower active pattern.

12. A method for manufacturing a display device, the method comprising:
forming a plurality of sub-pixels in a display area on a substrate including the display area and a peripheral area surrounding at least a portion of the display area;
forming a first transistor of a gate driver in the peripheral area on the substrate;
forming a second transistor of the gate driver in the peripheral area on the first transistor;
forming an inorganic insulating layer covering the second transistor; and
forming a plurality of through holes adjacent to the second transistor and spaced apart from each other by penetrating the inorganic insulating layer.

13. The method of claim 12, further comprising:
forming a via insulating layer filling interiors of the plurality of through holes and including an organic material on the inorganic insulating layer.

14. The method of claim 12, wherein the first transistor and the second transistor include a metal oxide semiconductor.

15. The method of claim 12, wherein the forming the second transistor includes:
forming an upper active pattern including a metal oxide semiconductor; and
forming an upper gate electrode overlapping a channel region of the upper active pattern in a plan view.

16. The method of claim 15, further comprising:
forming a contact hole penetrating the inorganic insulating layer and exposing a conductive region of the upper active pattern; and
forming a middle connection pattern connected to the conductive region of the upper active pattern through the contact hole.

17. The method of claim 16, wherein the plurality of through holes are formed through a same process as the contact hole.

18. The method of claim 12, wherein the plurality of through holes include:
a plurality of first through holes adjacent to the second transistor and spaced apart from each other in the peripheral area; and
a plurality of second through holes spaced apart from each other in the display area.

19. An electronic device comprising:
a processor configured to provide an image data signal and an input control signal; and
a display device configured to output image information based on the image data signal and the input control signal,
wherein the display device includes:
a substate including a display area and a peripheral area surrounding at least a portion of the display area;
a plurality of sub-pixels in the display area on the substrate;
a first transistor of a gate driver in the peripheral area on the substrate and including a metal oxide semiconductor;
a second transistor of the gate driver in the peripheral area on the first transistor and including a metal oxide semiconductor; and
an inorganic insulating layer covering the second transistor and defining a plurality of through holes adjacent to the second transistor and spaced apart from each other.

20. The electronic device of claim 19, wherein the display device further includes:
a via insulating layer on the inorganic insulating layer, filling interiors of the plurality of through holes, and including an organic material.
